(19) United States
(12) Patent Application Publication
(10) Pub. No.: US 2022/0237354 A1
(43) Pub. Date: Jul. 28, 2022

(54) GENERATING DIGITAL CIRCUITS

(71) Applicant: Beetlebox Ltd., London (GB)

(72) Inventor: Andrew Swirski, London (GB)

(21) Appl. No.: 17/627,332

(22) PCT Filed: Jul. 16, 2020
(86) PCT No.: PCT/GB2020/051708

§ 371 Date: Jan. 14, 2022

(30) Foreign Application Priority Data
Jul. 16, 2019 (GB) 1910179.9

(51) Int. Cl. G06F 30/343; G06F 30/347

(52) U.S. Cl. CPC G06F 30/343; G06F 30/347

(57) ABSTRACT

There is provided a computer-implemented method for determining a hardware description which specifies the behaviour of a digital circuit. The method comprises obtaining data defining a finite state machine and determining one or more expression evaluation logic operations, wherein conditional expressions can be evaluated by one or more of the expression evaluation logic operations. Subsequently, the method includes defining a circuit signal to represent the current state of the finite state machine and determining one or more state-transition logic operations effective to transition the current state of the finite state machine in accordance with the transitions specified by edges within the finite state machine. From this, the method may generate a hardware description which specifies the behaviour of a digital circuit which, in operation, performs the finite state machine.

### RELATED APPLICATION

The present application is a national stage application under 35 U.S.C. § 371 of International Application No. PCT/GB2020/051708, filed 16 Jul. 2020, which claims priority to Great Britain Patent Application No. 1910179.9, filed 16 Jul. 2019. The above referenced applications are hereby incorporated by reference.

### FIELD

The present disclosure relates to generating a hardware description which specifies the behaviour of a digital circuit. In particular, the present disclosure relates to determining a hardware description which specifies the behaviour of a digital circuit which implements a given finite state-machine.

### BACKGROUND

Digital circuits, such as Field-Programmable Gate Arrays (FPGA), Application-Specific Integrated Circuits (ASIC) or Complex Programmable Logic Devices (CPLD), implement their functionality through the interconnection of their hardware components. Compared to performing a functionality in software running on a processor, implementing functionality directly in hardware allows the choice, placement, and interconnection of the hardware components to be tailored to the function to be performed, leading to reduced latency, improved throughput, and reduced power consumption.

A developer wishing to implement a particular functionality in hardware will typically determine a hardware description which specifies the behaviour of a digital circuit which implements the particular functionality in a particular way. However, the relationship between a given hardware description and its functionality can be complex and not immediately apparent, because a circuit's functionality often emerges out of complex and disparate interactions of its circuit elements. As a result, determining a hardware description of a circuit to implement a particular functionality has traditionally been a difficult and lengthy process. Moreover, such a process needs to be repeated when scaling a small design to a large one, and when transferring a design from one type of hardware to another.

Faced with this issue, vendors have introduced high-level synthesis tools where the developer specifies in a high-level language a functionality to be implemented, and which then generate a hardware description performing the specified functionality. However, the resulting hardware description tends to be suboptimal among the set of all possible hardware descriptions capable of implementing the specified functionality. That is to say, where a number of potential hardware descriptions exist, these approaches do not allow a developer to control the outcome in such a way as to select the description most suited to their commercial or technical needs.

### SUMMARY

According to a first aspect, there is provided a computer-implemented method for determining a hardware description which specifies the behaviour of a digital circuit, where the hardware description defines a plurality of circuit signals and a plurality of logic operations, and where each logic operation takes as input one or more circuit signals and outputs to one or more circuit signals.

The method comprises a first step of obtaining data defining a finite state machine. This data defines a plurality of states of the finite state machine, a plurality of edges of the finite state machine, one or more variables on which the finite state machine operates, and one or more conditional expressions depending on one or more of the variables. Each defined edge specifies a possible transition of the current state of the finite state machine from a respective start state to a respective end state; furthermore, one or more edges of the finite state machine specify a possible transition of the current state from a respective start state to the respective end state in dependence on the value of a respective one of the conditional expressions. Moreover, the data may specify one or more aspects of the timing and physical implementation of the finite state machine. The method further comprises a step of determining one or more expression evaluation logic operations, where each conditional expression can be evaluated by one or more of the expression evaluation logic operations. The method also comprises a step of determining one or more state-transition logic operations effective to transition the current state of the finite state machine in accordance with the transitions specified by the edges. Finally, the method also comprises a step of generating a hardware description which specifies the behaviour of a digital circuit which, in operation, performs the finite state machine, wherein the hardware description comprises the circuit signal representing the current state of the finite state machine, the expression evaluation logic operations, and the state-transition logic operations.

Aspects of the present disclosure may enable the user to specify a desired digital circuit behaviour concisely in the form of data describing a finite state machine, thereby reducing the amount of user input needed to specify the desired digital circuit behaviour in comparison with directly writing a hardware description language, for example. Moreover, aspects of the present disclosure may provide guarantees on the consistency and behaviour of the generated hardware description, which may be difficult to check for and enforce for an arbitrary (manually-written) hardware description. At the same time, compared to specifying a desired digital circuit behaviour in a high-level synthesis language and generating a hardware description using a high-level synthesis tool, aspects of the present disclosure may provide greater control to the user, enabling a more precise specification of the desired digital circuit behaviour. For example, defining the digital circuit behaviour in terms of a finite state machine enables a timing target of one state transition per clock cycle to be specified and enforced throughout the method, whereas timing targets are typically difficult to guarantee when generating a hardware description from a high-level synthesis specification. As another example, by mapping the circuit signals specified in the data describing a finite state machine into the generated hardware description, the user may be provided more precise control over the circuit signals in the generated hardware description.

In some embodiments, the data defining a finite state machine defines one or more circuit signals to each represent a variable. Additionally, determining one or more expression evaluation logic operations may comprise determining one or more expression evaluation logic operations whose combination takes as input one or more of the circuit signals representing variables and outputs to one or more of the circuit signals representing variables. Additionally, determining one or more state-transition logic operations may comprise determining one or more state-transition logic operations whose combination takes as input the circuit signal representing the current state and the outputs of the expression evaluation logic operations, and outputs to the circuit signal representing the current state of the finite state machine

Optionally, the data defining one or more circuit signals additionally defines, for each circuit signal representing a variable, the circuit signal to be either of an input, an internal signal or an output.

Optionally, the data defining a finite state machine additionally defines, for each of one or more circuit signals representing variables, the circuit signal to be either of a registered signal or a combinational signal. Moreover, determining one or more expression evaluation logic operations may further comprise defining, as expression evaluation logic operations, a plurality of logic operations corresponding to one or more registers for storing the registered signals.

In this way, the user may be provided with precise control over the registers to be defined in the generated hardware description.

Optionally, the data describing a finite state machine comprises one or more state declarations and one or more edge declarations which together define the plurality of states and the plurality of edges. Each state declaration may define a state of the finite state machine and may comprise zero or more references to edge declarations, each corresponding to an outgoing edge of the state, and each edge declaration may comprise exactly one reference to a state declaration, corresponding to the end state of all edges defined with reference to the edge declaration.

In some embodiments, determining one or more expression evaluation logic operations comprises determining a schedule of one or more elementary instructions each scheduled for a state. For any particular state, the elementary instructions scheduled for the particular state are collectively effective to evaluate the conditional expressions on which the edges leading out of the particular state depend. Additionally, determining one or more expression evaluation logic operations may further comprise defining, as expression evaluation logic operations, one or more logic operations capable of performing the elementary instructions, such that for each state, all elementary instructions scheduled for that state can be simultaneously evaluated by the one or more logic operations.

By determining such a schedule of one or more elementary instructions each scheduled for a state, and defining logic operations capable of performing the elementary instructions, such that for each state, all elementary instructions scheduled for that state can be simultaneously evaluated by the one or more logic operations, the timing target of one state transition per clock cycle is ensured.

Additionally, defining, as expression evaluation logic operations, one or more logic operations capable of performing the elementary instructions may optionally comprise steps of maintaining a list of modules; iterating through each elementary instruction in the schedule; determining for each elementary instruction whether a module in the list is available to perform the operation in the state it is scheduled for: if a module in the list is available to perform the elementary instruction in the state it is scheduled for, assigning the elementary instruction to be performed by the module in the state it is scheduled for; otherwise, newly defining a module capable of performing the elementary instruction, inserting the newly-defined module in the list, and assigning the elementary instruction to the newly-defined module; and defining, for each module, one or more logic operations corresponding to the module as expression evaluation logic operations.

Additionally, defining, for each module, one or more logic operations corresponding to the module as expression evaluation logic operations may comprise defining, for each module, one or more logic operations corresponding to the module and optimised for a target hardware as expression evaluation logic operations. One of the modules may comprise an adder, a multiplier, a random-access memory (RAM) or a read-only memory (ROM).

In some embodiments, the data defining the finite state machine further defines, for each of one or more states of the finite state machine, one or more expressions to be evaluated at the state, each taking as input the value of one or more variables and assigning its output value to a variable, and determining a schedule of one or more elementary instructions each scheduled for a state comprises scheduling for each state one or more elementary instructions such that the elementary instructions scheduled for a state and for each incoming state with an edge leading to the state are collectively effective to evaluate the one or more expressions to be evaluated at the state. Additionally, scheduling for each state one or more elementary instructions such that the elementary instructions scheduled for a state and for each incoming state with an edge leading to the state are collectively effective to evaluate the one or more expressions to be evaluated at the state may comprise: for each state, scheduling for each incoming state with an edge leading to the state one or more elementary instructions effective to evaluate every expression to be performed at the state which assigns its result to a registered signal.

In this way, the functionality that can be described by a finite state machine may be expanded. At the same time, the timing target of one state transition per clock cycle may be preserved despite the expanded functionality.

In some embodiments, the data defining the finite state machine further defines, for each of one or more edges of the finite state machine, one or more expressions to be evaluated when the current state of the finite state machine transitions from the edge's start state to the edge's end state, each expression taking as input one or more variables and assigning its output value to a variable, and determining a schedule of one or more elementary instructions each scheduled for a state comprises, for each state, scheduling for the state one or more elementary instructions, such that the elementary instructions scheduled for the state are collectively effective to evaluate all the expressions defined for all the edges outgoing from the state. Additionally, determining a schedule of one or more elementary instructions each scheduled for a state further may further comprise verifying that each expression defined for an edge assigns its result to a circuit signal that is a combinational signal. Furthermore, determining a schedule of one or more elementary instructions each scheduled for a state may further comprise verifying that all variables on which conditional expressions depend are represented by registered signals or input signals.

In this way, the functionality that can be described by a finite state machine may be expanded. At the same time, the timing target of one state transition per clock cycle may be preserved despite the expanded functionality.

In some embodiments, the data defining the finite state machine defines one state of the finite state machine as an initial current state of the finite state machine, and determining one or more state-transition logic operations comprises defining, as state transition logic operations, one or more logic operations effective to set the circuit signal representing the current state of the state machine to the initial current state upon initialising the digital circuit. Additionally, the data defining a finite state machine may further define an initial value for each variable upon initialising the digital circuit, and determining one or more state-transition logic operations may further comprise defining, as state transition logic operations, one or more logic operations effective to set, upon initialising the digital circuit, the value of each circuit signal to represent the initial value of the corresponding variable. In this way, it may be ensured that at any time in the operation of a digital circuit specified by the data defining a finite state machine, the value of each variable is explicitly specified by the data defining the finite state machine. This affords greater control over the resulting hardware description to the programmer.

According to another aspect of the invention, there is provided a process for producing a digital circuit, comprising generating a hardware description specifying the behaviour of a digital circuit, according to the method for generating a hardware description described above; generating a digital circuit layout based on the hardware description; and manufacturing a digital circuit according to the digital circuit layout.

According to a further aspect of the invention, there is provided a process for programming a configuration circuit for configuring a Field-Programmable Gate Array, the process comprising: generating a hardware description specifying the behaviour of a digital circuit, according to the method for generating a hardware description described above; determining a configuration for each configurable component of the Field-Programmable Gate Array; and programming the configuration circuit to configure the configurable components of the Field-Programmable Gate Array according to the determined configuration.

According to another aspect of the invention, there is provided a process for configuring a digital circuit comprising a Field-Programmable Gate Array, the process comprising: programming a configuration circuit for configuring the Field-Programmable Gate Array according to the process for programming a configuration circuit described above; and assembling the configuration circuit and the Field-Programmable Gate Array into the digital circuit, wherein the digital circuit electronically connects the configuration circuit and the Field-Programmable Gate Array.

### BRIEF DESCRIPTION OF THE DRAWINGS

FIG. 1 depicts an example Field-Programmable Gate Array (FPGA).

FIG. 2 depicts an example hardware description of a digital circuit.

FIG. 3 depicts a text file hardware description in VHDL corresponding to the hardware description of FIG. 2.

FIG. 4 shows a method for generating a hardware description of a digital circuit given a specification of the desired behaviour of the digital circuit, according to embodiments of the present invention.

FIG. 5A depicts a text file describing an augmented finite state machine, according to embodiments of the present invention.

FIG. 5B depicts a graphical representation of the finite state machine described by the text file of FIG. 5A, according to embodiments of the present invention.

FIG. 5C depicts another graphical representation of the finite state machine described by the text file of FIG. 5A, according to embodiments of the present invention.

FIG. 6 depicts an example text file comprising variable declarations, according to embodiments of the present invention.

FIG. 7A depicts another text file describing an augmented finite state machine, according to embodiments of the present invention.

FIG. 7B depicts a graphical representation of the finite state machine described by the text file of FIG. 7A, according to embodiments of the present invention.

FIG. 8 shows a method for determining a set of variables, a set of constants, a schedule of instructions and a state transition table, according to embodiments of the present invention.

FIG. 9 shows a method for decomposing expressions into variables, constants and instructions, completing a set of variables and a set of constants, and constructing a schedule of elementary instructions and a state transition table, according to embodiments of the present invention.

FIG. 10A shows a set of variables produced by embodiments of the present invention for the text file describing an augmented finite state machine of FIG. 7A.

FIG. 10B shows a set of constants produced by embodiments of the present invention based on the text file of FIG. 7A.

FIG. 11 shows a schedule of elementary instructions produced by embodiments of the present invention based on the text file of FIG. 7A.

FIG. 12 shows a state transition table produced by embodiments of the present invention based on the text file of FIG. 7A.

FIG. 13 shows a method for generating a hardware description implementing the finite state machine, based on the set of variables, set of constants, schedule of instructions and state transition table, according to embodiments of the present invention.

FIG. 14 shows a method for determining one or more modules and assigning each of one or more elementary instructions to be performed by a module, according to embodiments of the present invention.

FIG. 15 shows a module allocator produced by embodiments of the present invention based on the text file of FIG. 7A.

FIG. 16 shows a module linker produced by embodiments of the present invention based on the text file of FIG. 7A.

FIG. 17 shows a method for generating a hardware description, based on a set of variables, set of constants, schedule of elementary instructions, state transition table, modules, and circuit signals to be connected to each module's inputs and outputs at each clock cycle, according to embodiments of the present invention.

FIG. 18A shows an entity shell of an output hardware description produced by embodiments of the present invention based on the text file of FIG. 7A.

FIG. 18B shows a signal shell of an output hardware description produced by embodiments of the present invention based on the text file of FIG. 7A.

FIG. 18C shows a module shell of an output hardware description produced by embodiments of the present invention based on the text file of FIG. 7A.

FIG. 18D shows a module instance shell of an output hardware description produced by embodiments of the present invention based on the text file of FIG. 7A.

FIG. 18E shows a combinational shell of an output hardware description produced by embodiments of the present invention based on the text file of FIG. 7A.

FIG. 18F shows a synchronous shell of an output hardware description produced by embodiments of the present invention based on the text file of FIG. 7A.

FIG. 19 shows a process for producing a digital circuit implementing an augmented finite state machine, according to embodiments of the present invention.

### DETAILED DESCRIPTION

Embodiments described herein involve generating a hardware description which specifies the behaviour of a digital circuit given a finite state machine (FSM) to implement. The hardware description can then be used to configure a Field-Programmable Gate Array (FPGA), or produce a digital circuit which implements the finite state machine.

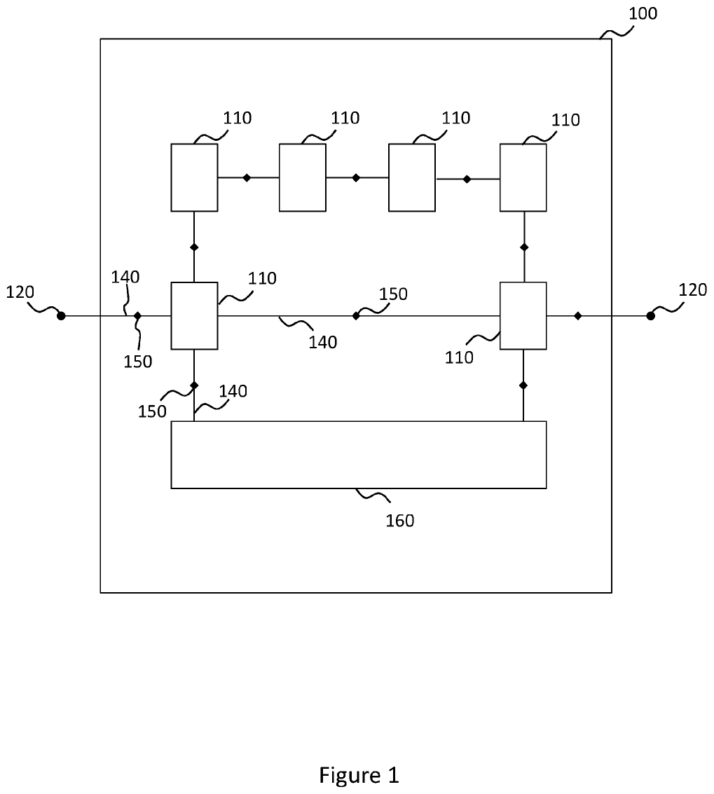

The concepts of an FPGA and a hardware description are now described with reference to FIGS. 1-3.

An example of a FPGA is illustrated in FIG. 1. The FPGA 100 is an integrated circuit which internally comprises a plurality of programmable logic blocks 110, which are connected to one another and to the FPGA's interface pins 120 in a routing matrix, composed of routing wires 140 and programmable switches 150, which control how the routing matrix connects the programmable logic blocks 110 to one another and to the interface pins 120. To avoid cluttering the figure, not all routing wires and programmable switches are shown. Typically, the programmable logic blocks 110 can be arranged in a rectangular mesh as shown in FIG. 1, where a programmable logic block can be connected to adjacent programmable logic blocks by routing wires 140 depending on the configuration of the programmable switches 150. Additionally, some routing wires 140 and programmable switches 150 can provide for long-distance connections between programmable logic blocks situated a long distance apart.

Each routing wire 140 is capable of carrying a digital signal, that is, a signal that can take one of several discrete values at every time instant. A routing wire may for example carry a digital signal represented by a voltage of the routing wire. For example, a routing wire may carry a binary-valued digital signal represented by its voltage, where the value of the digital signal is a 1 or 0 depending on whether the voltage is above or under a threshold voltage.

Each programmable logic block 110 performs a logic function that is configurable. A programmable logic block 110 may be connected to one or more routing wires as input, may perform a configurable logic function on the digital signals carried by the input routing wires, and, based on the result of the configurable logic function, may then set (i.e. generate) one or more digital signals which are carried by one or more routing wires, and/or set the values stored in one or more storage elements. Typically, the configurable logic function is performed by a look-up table (LUT), which can be configured to implement an arbitrary logic function of its inputs, or a combination of several LUTs. Thus, each programmable logic block is capable of performing a wide variety of different logic functions on its inputs, in dependence on how it is configured.

In addition, by configuring the programmable switches 150, it is possible to vary how the programmable logic blocks 110 are connected to one another and to the interface pins 120 by the routing wires 140. In this way, complex functionality can be created by combining the logic functions of the individual programmable logic blocks 110.

In addition to the programmable logic blocks 110 which can be configured to a large degree, the FPGA 100 may also comprise one or more modules 160 which perform specialised functions, such as integer or floating-point adders or multipliers, RAM memory, network interface controllers or microprocessors. In this case, any such modules 160 may be configurably connected via the routing matrix to the programmable logic blocks 110, to the interface pins 120 and to each other.

Thus, by configuring the programmable logic blocks 110 and the programmable switches 150, the FPGA 100 can be configured to implement a wide variety of functionalities. The FPGA effectively operates as a custom-defined digital circuit, where the nature of the circuit elements and the structure of their interconnections are respectively determined by the configurations of the programmable logic blocks 110 and of the programmable switches 150.

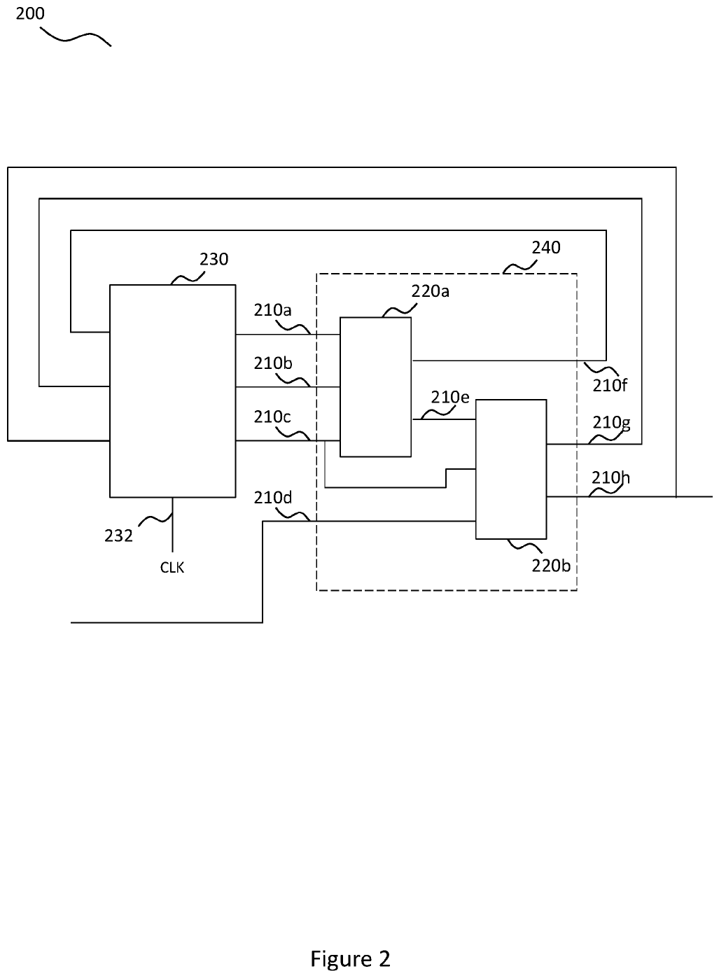

Turning to FIG. 2, a hardware description of a digital circuit is illustrated. Broadly speaking, a hardware description is a description of a digital circuit at a behavioural level. A hardware description specifies the behaviour of a synchronous digital circuit by defining a plurality of circuit signals 210, a plurality of logic operations 220, and zero or more registers 230. Each logic operation 220 operates on the value of one or more of circuit signals 210 and sets the value of one or more circuit signals 210 as a result, and each register 230 has one or more input circuit signals 210 and one or more output circuit signals 210. A hardware description can typically be written in a hardware description language, such as Very High Speed Integrated-Circuit Hardware Description Language (VHDL) or Verilog.

A circuit signal is an entity in a hardware description which signifies that provision is made in a digital circuit for one or more physical components corresponding to the circuit signal to carry one or more digital signals which collectively encode a value for the circuit signal. For example, a circuit signal in a hardware description may specify the existence of one or more electrical wires in a corresponding digital circuit, whose voltages are digital signals which collectively encode a value for the circuit signal; the same circuit signal may specify the existence of one or more waveguides carrying an electromagnetic wave in a digital RF circuit, where the electric (or magnetic) fields at an end of each waveguide are digital signals which collectively encode a value for the circuit signal; and the same circuit signal may specify the existence of one or more optical fibres carrying light in a photonic circuit, where light intensities in the optical fibres collectively encode a value for the circuit signal.

For example, a circuit signal may be defined that provides for encoding a single bit. Such a circuit signal may correspond to a single electrical wire in a digital circuit, whose voltage can be determined to be either of a high or low value. A circuit signal can take one of a discrete number of possible values; typically, the number of possible values is a power of 2, where the exponent corresponds to the number of bits represented by the circuit signal, and is called the signal's width.

The skilled person will appreciate that there may be several different possible ways to implement a circuit signal in a corresponding digital circuit. For example, a circuit signal providing for carrying a four-bit variable may alternatively be implemented by a single electrical wire carrying a serial bit-stream encoding the four-bit variable, or four parallel electrical wires each carrying one bit of the four bits, or 16 electrical wires carrying a one-hot encoding of the variable.

A logic operation is an entity in a hardware description which signifies that provision is made in a digital circuit for one or more physical components corresponding to the logic operation to perform a digital function on the values of one or more circuit signals, and to set the values of one or more circuit signals based on the result of the digital function. The circuit signals on which the logic operation performs a digital function are referred to as the logic operation's inputs, and the circuit signals whose values the logic operation sets are referred to as the logic operation's outputs. Since each circuit signal takes one of a discrete number of values, a logic operation may be defined by exhaustively listing the resulting values of the outputs for every possible combination of the initial values of the inputs, which can be represented in a table. A logic operation may also be defined in terms of one or more operators (e.g. a bitwise ‘and’ operator), assignments (e.g. assigning the result of an operator to a circuit signal), and/or control flow statements (e.g. an if-then statement) in a hardware description language.

A logic operation may be performed by one or more combinational circuit components in a digital circuit whose behaviour is described by the hardware description. As a result, during operation of the circuit, if the values of a logic operation's inputs change, the values of the logic operation's outputs may automatically change in response, after a propagation delay caused by the switching times of the combinational circuit components. For instance, an example logic operation is an integer addition of two circuit signals each representing an integer, which may be implemented by an integer adder in the corresponding digital circuit. Another example logic operation is setting a circuit signal to one of a plurality of other circuit signals, based on the value of a controlling circuit signal, which may be implemented by a demultiplexer in the corresponding digital circuit.

Typically, a circuit signal may be set by only one logic operation at any one time. This is because if two physical components attempt to set the voltage of a single wire simultaneously, a short-circuit can ensue. As a result, in many cases a logic operation will consistently use some signals as inputs and other signals as outputs. However, in other cases, a same circuit signal, such a bidirectional bus, may be used alternatively as an input and as an output by a logic operation.

It will be also be recognised by the skilled person that multiple logic operations can be understood in combination as a single logic operation, which interacts with all the circuit signals of its component logic operations, except those which solely connect its component logic operations to one another. For example, in FIG. 2, the two logic operations 220a and 220b can be understood as a single logic operation 240, which interacts with all the circuit signals 210a-h except circuit signal 210e.

A register is an entity in a hardware description that signifies that provision is made in a digital circuit for a synchronous memory element which is capable of storing one or more values. In particular, a register may be defined as connected to one or more circuit signals as inputs and one or more circuit signals as outputs, where there is a one-to-one correspondence between the stored values, the inputs and the outputs. Furthermore, a register may further specify that provision is made in the digital circuit for a clock signal which indicates a plurality of discrete instants of time—such a clock signal may itself be defined in the hardware description, labelled 232 in FIG. 2. During operation of the digital circuit, the synchronous memory element may at all times set the value of each output to the corresponding stored value. At each of the plural discrete instants of time, the synchronous memory element may update each stored value with the value of the corresponding input.

The hardware description may specify one or more circuit signals to be input circuit signals, i.e. to represent one or more inputs whose values are set from outside the digital circuit. For example, in FIG. 2, circuit signal 210d is an input. Furthermore, the hardware description may specify one or more circuit signals to be output circuit signals, whose values are made available outside the digital circuit.

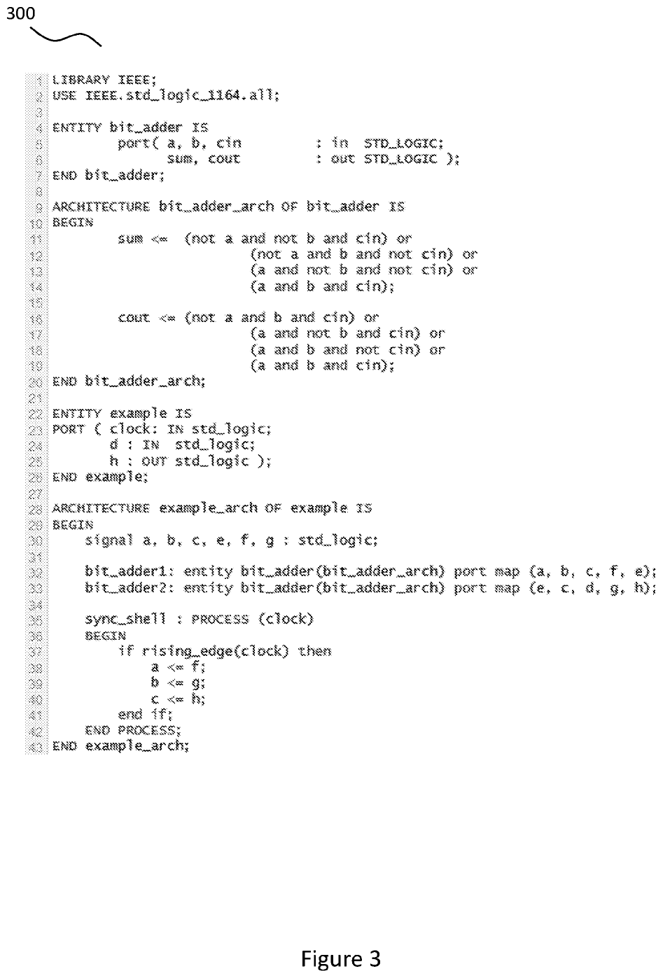

Turning to FIG. 3, an example text file hardware description in VHDL is depicted, which may describe the behaviour of the same circuit as the example hardware description of FIG. 2.

At lines 23-25 and 30, ten circuit signals are defined: a “clock” circuit signal, which corresponds to the clock signal 232 of FIG. 2, and circuit signals “a”, “b”, “c”, “d”, “e”, “f”, “g” and “h”, which respectively correspond to circuit signals 210a-210h of FIG. 2.

At lines 23-25, circuit signal “d” is defined to be an input circuit signal, and circuit signal “h” is defined to be an output circuit signal.

At lines 32 and 33, two logic operations are defined, “bit_adder1” and “bit_adder2”, which respectively correspond to logic operations 220a and 220b of FIG. 2. Both of those logic operations are bit adders, which take three circuit signals as input and output to two circuit signals. At lines 32 and 33, it is specified that logic operation “bit_adder1” takes circuit signals “a”, “b” and “c” as inputs, and outputs to circuit signals “f” and “e”, and that logic operation “bit_adder2” takes circuit signals “e”, “c” and “d” as inputs, and outputs to circuit signals “g” and “h”. The two logic operations “bit_adder1” and “bit_adder2” may however be understood as a single logic operation defined by lines 32 and 33, which takes as input circuit signals “a”, “b”, “c”, “d” and “e”, and outputs to circuit signals “f”, “g” and “h”.

At lines 37-41, a register is defined, which corresponds to register 230 of FIG. 2. The register is capable of storing three one-bit values, which are respectively output to circuit signals “f”, “g” and “h”. Furthermore, lines 37-41 specify that at each rising edge of the clock signal, the stored value corresponding to circuit signal “f” is updated to the value of circuit signal “a”, the stored value corresponding to circuit signal “g” is updated to the value of circuit signal “b”, and the stored value corresponding to circuit signal “h” is updated to the value of circuit signal “c”.

Specifying the configuration of a FPGA to perform some functionality often involves, as an intermediate step, determining a hardware description which specifies the behaviour of a digital circuit capable of performing the functionality. Indeed, given a hardware description that specifies a behaviour of a digital circuit, it is often possible to obtain a configuration for an FPGA such that the FPGA implements the behaviour. In addition, a hardware description can also serve to obtain not only a configuration for a FPGA, but also a configuration of a Complex Programmable Logic Device (CPLD) or the layout of an Application-Specific Integrated Circuit (ASIC) which implements the same behaviour.

It is thus highly desirable to have a tool that given some functionality, determines a hardware description for performing it, since such a tool allows determining a configuration for a FPGA that enables it to perform the functionality or the layout of an ASIC that enables it to perform the functionality.

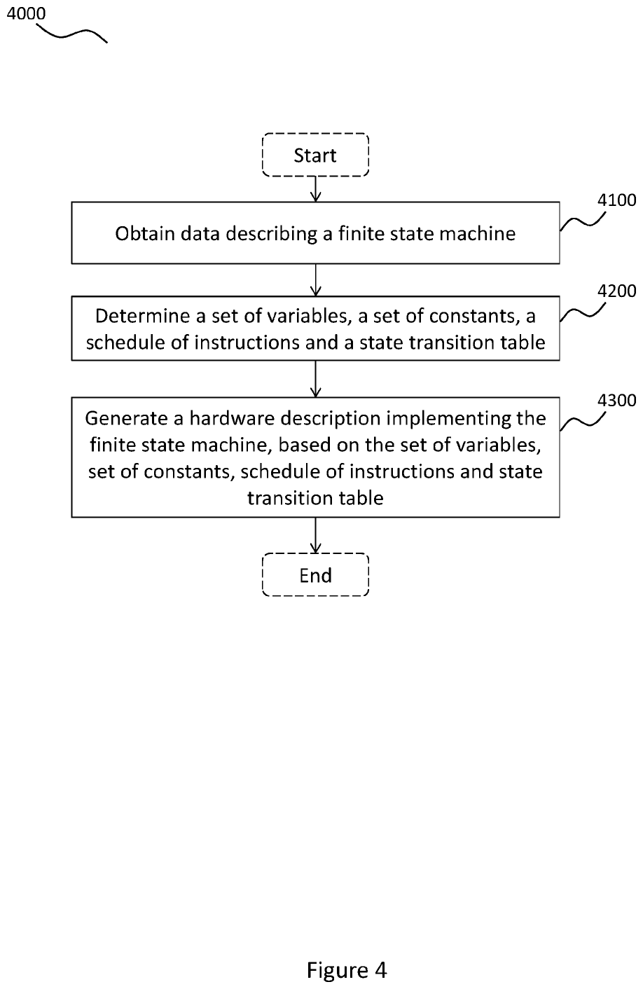

FIG. 4 shows a method 4000 which, given a specification of a behaviour of a digital circuit in the form of an augmented finite state machine, generates a hardware description of a digital circuit having the specified behaviour. In the rest of this specification, a digital circuit having a behaviour specified by data describing a particular augmented state machine is said to implement the particular augmented finite state machine.

At step 4100, data describing a behaviour of a digital circuit is obtained in the form of data describing an augmented finite state machine. The data describing an augmented finite state machine may be a text file stored in computer-readable memory or a graphical representation stored in computer-readable memory, for example.

A finite state machine is a model of a computational device. A finite state machine has a current state, which is a variable whose value can take one of a finite set of possible states. The finite state machine is said to be at a particular state when the current state is the particular state. In response to an event, the finite state machine can update the value of its current state, a process known as a transition. The transition is performed based on a state diagram, where the state diagram describes, for each state, how the machine, when its current state is the state, should update the value of its current state in response to each event that may occur. Thus, the transition depends only on the value of the current state before it is changed and on the event that occurs. A possible update of the current state from a start state to an end state is called an edge. Each edge is specified by its respective start state, its respective end state, and its respective triggering event. An edge specifies that if the triggering event occurs when the current state is the start state, the current state should be updated to the end state. Each edge is said to be an outgoing edge of its start state, and an incoming edge of its end state. Finally, the start state and the end state of an edge may be the same state, in which case the finite state machine may still transition from a state to itself; such an edge is referred to as a circular edge. A finite state machine may be described by its set of possible states and its set of edges, where the edges specify, for each state in the set of states, the transition to be performed in response to any event which may occur when the finite state machine is at the state.

The data obtained at step 4100 may thus explicitly or implicitly define a plurality of states and edges of the finite state machine, where each state is a possible value for the current state of the state machine, and where each edge of the finite state machine links a respective start state of the edge to a respective end state of the edge.

The data obtained at step 4100 is said to describe an augmented finite state machine in that it describes a finite state machine that has been augmented with additional information which specifies aspects of the timing of its operation and/or aspects of its physical implementation, thereby specifying a behaviour of a digital circuit with greater precision. These may enable the method to optimise the generated hardware description, leading to an output hardware description with improved performance in terms of circuit speed, area and power consumption. In other words, the data describing an augmented finite state machine is apt to specify the behaviour of a real digital circuit in a precise way, rather than merely specifying an abstract model of computation which cannot be efficiently transposed to a real digital circuit. Furthermore, a user who writes data describing an augmented finite state machine is afforded finer-grained control in specifying a behaviour of a digital circuit, than a non-augmented finite state machine would provide.

In particular, the data may describe a finite state machine that is augmented in one or more of several ways described below.

The data describing an augmented finite state machine may comprise one or more state declarations and one or more edge declarations.

Each state declaration defines a different possible state of the finite state machine, and comprises zero or more references to edge declarations. In a state declaration, each reference to an edge declaration defines a different outgoing edge of the state defined by the state declaration. Each edge declaration comprises exactly one reference to a state declaration, which corresponds to the end state of the outgoing edges defined with reference to the edge declaration. A state declaration does not specify the end states of its outgoing edges; rather, for each outgoing edge, its end state is specified in the corresponding referenced edge declaration.

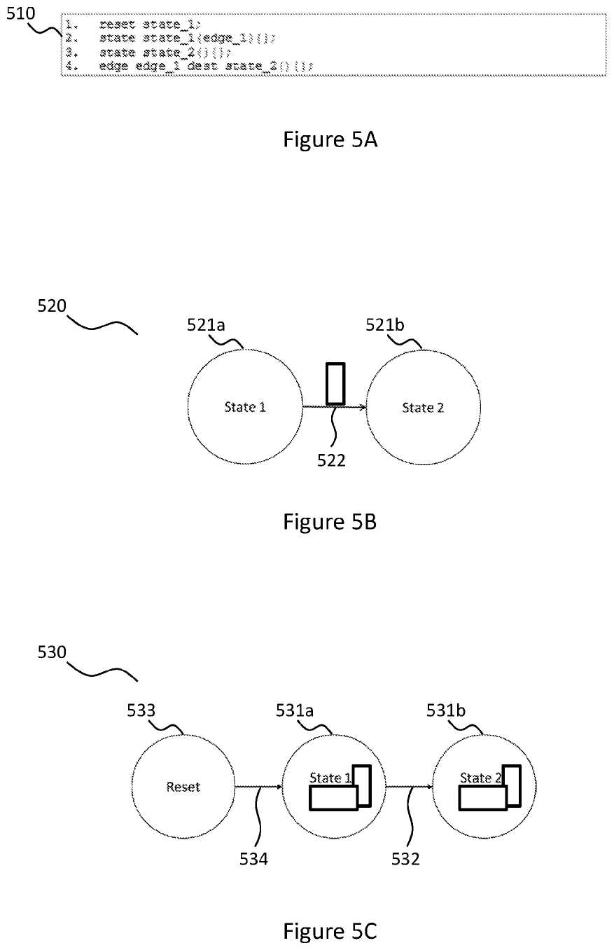

For example, FIG. 5A depicts an example text file 510 describing an augmented finite state machine. The statement at line 2, “state state_1 (edge_1) { };”, is a state declaration defining a first possible state of the finite state machine, named “state_1”, and comprising a reference to the edge declaration “edge_1”. The single reference to an edge declaration signifies that state “state_1” has exactly one outgoing edge, which is further defined in the edge declaration of “edge_1”. Similarly, the statement at line 3, “state state_2( ){ };”, is a state declaration defining a second possible state of the finite state machine, named “state_2”, and comprising no reference to an edge declaration, which signifies that state “state_2” does not have any outgoing edges. The statement at line 4, “edge edge_1 dest state_2 ( ){ };”, is an edge declaration which signifies that the end state of all outgoing edges defined with reference to “edge_1” is state “state_2”.

Thus, an edge declaration may be understood as defining a class of edges, rather than a single edge of the finite state machine. Each edge declaration may correspond to several actual edges of the finite state machine: one edge for each state declaration where the edge declaration is referenced.

In this way, the finite state machine may be defined through the state definitions and the edge definitions. Advantageously, by defining the finite state machine through state definitions and edge definitions, edges which perform the same function and have the same end state may have their function defined just once, in an edge definition, rather than many times, once for each actual edge, thus reducing code size. Furthermore, the functions of all the edges corresponding to a single edge definition may be performed by a single set of logic operations, thereby resulting in a simpler (and therefore, better performing) output hardware description than if the function of each actual edge was defined independently.

Furthermore, the finite state machine may be augmented in that the data describing an augmented finite state machine may designate a state to be the first state entered by the finite state machine after the initialisation of a digital circuit implementing the augmented finite state machine. That is, upon completing the initialisation of the digital circuit, the current state of the finite state machine implemented by the digital circuit is to be the designated state. In particular, if the current state of the finite state machine is implemented by storing the value of the current state in a memory element of the digital circuit, upon completing the initialisation of the digital circuit, the designated state is to be stored as the value of the current state m. In this way, the behaviour of a digital circuit described by the data describing an augmented finite state machine may be precisely defined from initialisation.

To this end, the data describing an augmented finite state machine may define a reset state, which denotes the initialisation phase (or re-initialisation following a reset) of a digital circuit implementing the augmented finite state machine. The data describing an augmented finite state machine may then designate a particular state of the finite state machine as the first state entered by the finite state machine upon completing the initialisation of the digital circuit by specifying the finite state machine to enter the particular state upon exiting the reset state. This may be graphically represented by an edge leading from the reset state to the particular state. The reset state need not be one of the possible states of the finite state machine, but may rather be a convenient notation for the initialisation of the digital circuit.

For example, turning back to FIG. 5A, the statement at line 1 of text file 510, “reset state_1”, defines a reset state corresponding to the initialisation of a digital circuit implementing the augmented finite state machine, and declares that state “state_1” is the first state to be entered by the finite state machine upon completing the initialisation of the digital circuit. That is, that upon completing the initialisation of the digital circuit, the current state is to be state “state_1”.

In addition, the data describing an augmented finite state machine may explicitly or implicitly specify that the transitions of the finite state machine are constrained to occur at one or more of plural discrete instants of time. The plural discrete instants of time may be periodic, for example occurring once every microsecond, once every tenth of microsecond, once every hundredth of microsecond, once every nanosecond, or any other suitable time interval. In this way, the finite state machine is made suitable for implementation by a synchronous digital circuit, in particular, one where the state of the finite state machine is represented by the values stored in one or more hardware registers, which may only change at discrete instants of time such as at the rising edge of a hardware clock, or at the falling edge of a hardware clock.

Furthermore, the data describing an augmented finite state machine may explicitly or implicitly specify that a digital circuit implementing the augmented finite state machine, in operation, is to perform exactly one state transition per clock cycle of a hardware clock of the digital circuit.

In a typical high-level synthesis tool, a timing target generally cannot be guaranteed to the user. Typically the user may specify a desired maximum number of clock cycles for performing a function. The high-level synthesis tool may attempt to generate a hardware description which fulfils this timing target. However, in general the high-level synthesis tool may fail to determine a hardware description that meets the desired timing target. As a result, a user who specifies a digital circuit in the high-level language may not know a priori whether a desired timing target will be achieved.

In contrast, method 4000 guarantees that the timing target of one state transition per clock cycle is met in the output hardware description. This is due not least to defining the desired digital circuit behaviour in terms of an augmented finite state machine, as well as the particular manner in which the evaluations of various expressions are scheduled at step 4240.

The augmented finite state machine described by the text file 510 of FIG. 5A may thus be graphically represented as graph 520 of FIG. 5B, which shows the two possible states 521a, 521b and the single edge 522 of the finite state machine. State 521a corresponds to the state declaration “state state_1 (edge_1) { };”, and state 521b corresponds to the state declaration “state state_2 ( ){ };”. The edge 522 whose start state is state 521a and end state is state 521b is specified by the state declaration “state state_1 (edge_1) { };” and the edge declaration “edge edge_1 dest state_2 ( ){ };”. The text file 510 thus specifies the operation of a digital circuit which, at the first hardware clock signal after initialisation is complete, stores state “state_1” as the value of the current state. At the next hardware clock signal, state “state_2” is stored as the value of the current state. The value of the current state then remains constant at state “state_2” for all subsequent clock periods, because state “state_2” has no outgoing edges.

Turning to FIG. 5C, the same augmented finite state machine is graphically represented in another way. As in FIG. 5B, the states “state_1” and “state_2” are represented by nodes, 531a and 531b, and the edge from “state_1” to “state_2” is represented by an edge, 532. Here, the designation of the state 531a as the first state entered by the finite state machine after initialisation is equivalently represented as connecting a reset state 533 to the state 531a via an edge 534. The reset state 533 and additional edge 534 simply serve to indicate that the state 531a is the first state to be entered by the finite state machine upon completion of the initialisation of a described digital circuit, and do not alter the digital circuit behaviour specified by the text file 510 of FIG. 5A.

In some embodiments, the data describing an augmented finite state machine may define for each of one or more of the states a latency, which specifies a number of clock cycles which the finite state machine should remain in the state every time the finite state machine transitions to the state. For example, a latency of zero may signify that the finite state machine should remain in the state for one clock cycle every time the finite state machine transitions to the state; a latency of one may signify that the finite state machine should remain in the state for two clock cycles every time the finite state machine transitions to the state, and so on. In general, a latency of n, with n greater than zero, may signify that expressions defined for the state (as will be described below) are to be evaluated n additional times, that is, the expressions defined for the state are to be evaluated for n+1 clock cycles. A state with a latency of n therefore is a shorthand notation for a chain of n+1 states, where each of the n+1 states perform the same function. The latency of a state may be a constant defined in the data describing an augmented finite state machine, or alternatively, may be the value of a variable or expression upon the finite state machine entering the state, where the variable or expression may be defined in the data describing an augmented finite state machine as described below.

The data describing an augmented finite state machine may additionally define one or more variables, which may be used in expressions which the finite state machine evaluates. For example, a variable may represent a boolean value, an integer, a floating-point number, a single character, or a sequence of characters, among other possibilities.

Furthermore, the data describing an augmented finite state machine may define for each variable a corresponding circuit signal. Such a circuit signal definition signifies that provision is to be made, in a digital circuit implementing the augmented finite state machine, for one or more physical components to carry the value of the variable as one or more digital signals. This may for example be achieved in any way described above in relation to a circuit signal in a hardware description. For example, a circuit signal may correspond to one or more wires in the resulting digital circuit whose voltages encode the value of the corresponding variable.

In some embodiments, the data describing an augmented finite state machine may define, for each circuit signal corresponding to a variable, the circuit signal to be an input circuit signal, an output circuit signal, or an internal circuit signal of a digital circuit implementing the augmented finite state machine. If a circuit signal is defined to be an input circuit signal, this signifies that provision is to be made to carry the value of the corresponding variable as one or more input digital signals—that is, a digital signals which are driven by physical components outside the digital circuit, and are available to be read inside the digital circuit, for example through an electrical connection with an interface pin of the digital circuit. If a circuit signal is defined to be an output circuit signal, this signifies that provision is to be made to carry the value of the corresponding variable as an output digital signal—that is, a digital signal which is generated within the digital circuit, and is made available to a physical component outside the digital circuit, for example through an electrical connection at an interface pin of the digital circuit. If a circuit signal is defined to be an internal circuit signal, this signifies that provision is to be made to carry the value of the corresponding variable as an internal digital signal—that is, a digital signal which is generated within the digital circuit and is only made available to physical components within the circuit.

Input digital signals, output digital signals and internal digital signals may have differing hardware requirements. In particular, each input or output digital signal may require reserving one or more interface pins of the digital circuit and associated hardware such as logic gates used to buffer or condition the signals at the interface pins. An internal digital signal may not have such requirements. Therefore, defining one or more circuit signals as input, output, or internal circuit signals in the data describing an augmented finite state machine enables method 4000 to optimise the use of hardware in the resulting hardware description, by making provision for interface pins and associated hardware components for exactly those circuit signals that require them.

In some embodiments, the data describing an augmented finite state machine may alternatively or additionally define, for each circuit signal corresponding to a variable, the circuit signal to be either of a registered circuit signal or a combinational circuit signal. If a circuit signal is defined to be a registered signal, this signifies that provision is to be made for the value of the corresponding variable to persist between clock cycles, until it is overwritten. In particular, the value of the corresponding variable may be stored in one or more memory elements, and the digital signals representing the value of the variable may be the output signals of those one or more memory elements storing the value of the variable. A memory element may be any physical component capable of persistently storing a value and providing this value as an output signal, such as a flip-flop or a static random access memory (SRAM) register. In this way, the value of a variable corresponding to a registered circuit signal can be preserved even when a variable on which it was based changes value; thus, in particular, the value of a variable corresponding to a registered circuit signal can be preserved between clock cycles, until it is overwritten.

Otherwise, if a circuit signal is defined to be a combinational signal, this signifies that no provision is to be made for the value of the corresponding variable to persist between clock cycles. In particular, a combinational signal need not have its value stored in a memory element; for example, a combinational signal may simply have its value stored as the voltage signal on one or more wires. Thus, the value of a variable corresponding to a combinational circuit signal may not be guaranteed to be preserved even when a variable on which it was based changes value. In particular, the value of a variable corresponding to a combinational circuit signal may not be guaranteed to be preserved between clock cycles.

Providing for a signal to persist between clock cycles may have a cost, in terms of space taken up by a memory element, increased power consumption caused by a memory element, propagation and switching delays in a memory element, and/or delays caused by synchronous memory that can only store a value every clock cycle. Thus, by differentiating between variables which need to persist between clock cycles and those which do not, method 4000 is enabled to optimise the use and allocation of memory elements in the output hardware description, leading to improved performance and reduced power consumption in a digital circuit described by the output hardware description.

Circuit signals which are defined to be input circuit signals may be inferred to be combinational circuit signals. Indeed, since an input digital signal is one that is set by a physical component outside the digital circuit, the digital circuit cannot control the persistence of such an input digital signal between clock cycles (or indeed even within a single clock cycle).

In addition, the data describing an augmented finite state machine may define a reset value for each of one or more variables not corresponding to input circuit signals. The reset value of a variable is a default value which the variable is taken to have if its value would be otherwise undefined by the data describing an augmented finite state machine. It may be unnecessary for the data describing an augmented finite state machine to define a reset value for a variable which corresponds to an input circuit signal, since the input digital signal carried by the input circuit signal may encode a valid value for the input circuit signal at all times, such that there would be no use for a default value.

A reset value of a variable corresponding to a registered circuit signal may thus be the initial value which the variable may be taken to have before its value is set in an expression (as will be described below) for the first time. In particular, specifying a reset value for a variable corresponding to a registered circuit signal may enable method 4000 to output a hardware description of a digital circuit such that the value of the registered circuit signal is set to the reset value during the initialisation of the digital circuit, as will be explained in more detail below, thereby enabling the circuit behaviour to be precisely defined. In order to ensure that variables corresponding to registered circuit signals are indeed set to their reset values upon entering the initial state of the finite state machine, the data describing an augmented finite state machine may explicitly or implicitly specify that the registered circuit signals are to be set to their reset values at least a full clock cycle before entering the initial state of the finite state machine. For example, the reset state may last for at least two clock cycles, and the variables corresponding to registered circuit signals may be set to their reset values in the first clock cycle of the reset state, thereby ensuring that the registers contain correct values upon entering the initial state.

Similarly, a reset value of a variable corresponding to a combinational circuit signal may be a default value which the variable may be taken to have in a clock cycle where its value is not otherwise set, which may for example be a clock cycle where no expression sets the value of the variable. In this way, at no point in the operation of a digital circuit described by the data describing an augmented finite state machine, is the value of a variable corresponding to a combinational signal undefined. Furthermore, by specifying a reset value for a variable corresponding to a combinational circuit signal, its value may be defined at all times without resorting to creating a latch in the digital circuit, which may cause the circuit to malfunction due to the latch's sensitivity to hazards.

In some embodiments, the data describing an augmented finite state machine may define the data types of one or more variables. For example, possible data types may include one or more boolean data types, one or more integer data types, one or more floating-point number data types, one or more character data types, and/or one or more data types composed from one or more of the previous data types, such as vector data types or structure data types.

The data type of a variable may define the number of bits to be used to represent the variable's value as well as how the value of the variable is represented by the values of the bits. For example, a variable which is of a signed 32-bit integer data type, int32, may have its value represented in 32 bits. This enables an appropriate width to be defined for the circuit signal corresponding to the variable: in particular, the width of the corresponding circuit signal may be set to the number of bits defined by the data type. For example, defining a variable as being of data type int32 may enable a suitable width of 32 bits to be chosen for the corresponding circuit signal.

Furthermore, the meaning of an operation involving one or more variables may be defined by the data types of the variables involved. For example, if two variables which are of an unsigned 32-bit integer data type, uint32, are added, this may signify that the addition is to be performed in integer arithmetic. On the other hand, if a variable of uint32 data type is added to a variable which is of a 32-bit floating-point number data type, this may signify that the addition is to be performed in floating-point arithmetic. Since such operations may feature in one or more expressions, as will be described later, defining the data types of one or more variables in the data describing an augmented finite state machine enables the result of expressions to be precisely and uniquely defined.

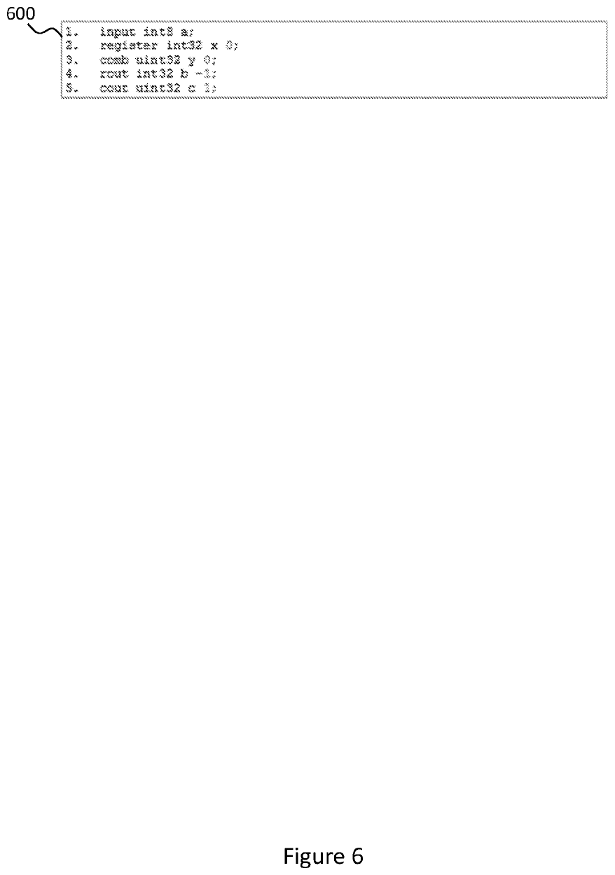

For example, FIG. 6 illustrates an example text file 600 comprising several variable declarations. At line 1, the variable declaration “input int8 a;” defines a variable named “a”, and defines an input circuit signal corresponding to “a” which is of type int8, that is, a signed 8-bit integer. At line 2, the variable declaration “register int32×0;” defines a variable named “x”, and defines a registered internal circuit signal corresponding to “x”, of type int32 and default value 0. At line 3, the variable declaration “comb uint32 y 0;” defines a variable named “y”, and defines a combinational internal circuit signal corresponding to “y”, of type uint32 and default value 0. At line 4, the variable declaration “rout int32 b −1;” defines a variable named “b”, and defines a registered output circuit signal corresponding to “b”, of type int32 and default value −1. At line 5, the variable declaration “cout uint32 c 1;” defines a variable named “c”, and defines a combinational output circuit signal corresponding to “c”, of type uint32 and default value 1.

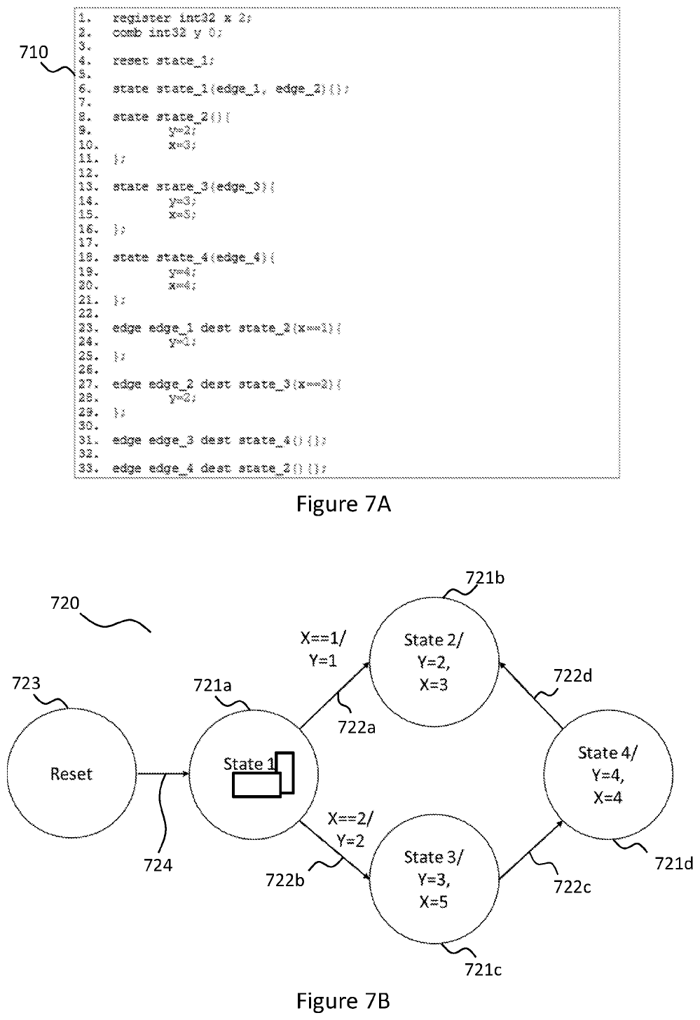

In another example, FIG. 7 depicts another example text file 710 describing an augmented finite state machine.

At line 1, the variable declaration “register int32×2;” defines a variable named “x”, and defines a registered internal circuit signal corresponding to “x”, of type “int 32” and default value 2. At line 2, the variable declaration “comb int32 y 0;” defines a variable named “y”, and defines a combinational internal circuit signal corresponding to “y”, of type int32 and default value 0.

At line 4, the statement “reset state_1;” designates a state of the finite state machine, “state_1”, as the first state to be entered by the finite state machine upon completing the initialisation of the digital circuit.

At line 6, the state declaration “state state_1 (edge_1, edge_2) { }” defines a possible state of the finite state machine, “state_1”, which has two outgoing edges, defined with reference to the edge declarations “edge_1” and “edge_2”.

Turning back to step 4100 of FIG. 4, the data describing an augmented finite state machine may additionally define one or more expressions to be evaluated by the finite state machine. Each expression has an output value which depends on the values of one or more of the variables, which are said to be the expression's input variables. The expression is said to depend on its one or more input variables. Evaluating an expression means obtaining its output value based on the values of its input variables.

One or more expressions which may be defined by the data describing an augmented finite state machine may be conditional expressions. A conditional expression is an expression whose output value is either true or false, depending on the values of its input variables.

For example, ‘a==1’ is a conditional expression, whose output value is true when the variable ‘a’ has a value equal to the constant 1, and false otherwise. Similarly, ‘a==0’ is also a conditional expression, whose output value is true when the variable a has a value equal to the constant 0, and false otherwise. Other examples of conditional expressions will be apparent to the skilled person, such as ‘a !=1’, whose output value is true when the variable a has a value not equal to 1, and false otherwise; ‘a>b’, whose output value is true when the variable ‘a’ has a value strictly greater than the value of the variable b, and false otherwise; ‘a+6<b’, whose output value is true when the result of evaluating the sum of the value of variable ‘a’ and 6 is strictly less than the value of variable ‘b’, and false otherwise; ‘a==0 and b==0’, whose output value is true when variables ‘a’ and ‘b’ are both equal to zero, and false otherwise.

The data describing an augmented finite state machine may associate each of one or more edges of the finite state machine with a respective conditional expression. A conditional expression associated with an edge signifies that if the finite state machine is at the start state of the edge, then the finite state machine will transition according to the edge only if the associated conditional expression is true. In particular, the finite state machine may transition according to the edge if the finite state machine is at the start state of the edge, the associated conditional expression is true, and the finite state machine is at one of the plural discrete instants of time. In other words, for each edge of the finite state machine, an event of the finite state machine may be defined to occur if the edge's corresponding conditional expression is true at one of the discrete time instants.

An edge which is not associated with a conditional expression may be regarded as having a conditional expression which is always true, such that the edge may always be taken.

Conditional expressions associated with edges may be specified within edge declarations. In particular, one or more of the edge declarations may each define a conditional expression, which is then associated with all the edges referring to the edge declaration. Since the evaluation of a conditional expression may typically be performed by the same hardware for all edges associated with the conditional expression, specifying a conditional expression within an edge declaration to which several actual edges of the finite state machine refer may enable significant optimisations to be performed by method 4000, as will be further explained below.

For instance, returning to the example text file 710 of FIG. 7, at lines 23-25, the edge declaration “edge edge_1 dest state_2 (x==1) y=1;};” specifies that all edges defined with reference to “edge_1” have a state “state_2” as their end state. The expression inside the parentheses “(x==1)” is a conditional expression associated with the edge, which signifies that all edges defined with reference to “edge_1” are conditional on the result of evaluating the expression “x==1” being true.

The outgoing edges at each state may be ordered; in this way, if at a state the conditional expressions of several outgoing edges are simultaneously true, the first outgoing edge according to the order whose conditional expression is true may be taken. In particular, the outgoing edges may be ordered in the order in which they are defined in the state definition: for example, for a state definition “state state_1 (edge_1, edge_2)”, the outgoing edge defined with reference to “edge_1” will be prioritised over the outgoing edge defined with reference to “edge_2”.

Furthermore, turning back to step 4100 of FIG. 4, the data describing an augmented finite state machine may define one or more expressions whose output values are assigned to variables. Each such expression may be defined for a state, in which case it is called a Moore expression, or may be defined for an edge, in which case it is called a Mealy expression.

For example, in the example text file 710 of FIG. 7, at lines 8-11 the state declaration “state state_2 ( ) {y=2; x=3;}” defines a state, “state_2”, and two Moore expressions, “y=2” and “x=3”. The Moore expression “y=2” signifies that upon the finite state machine entering the state “state_2”, the variable “y” is to be assigned the value 2. Similarly, the Moore expression “x=3” signifies that upon the finite state machine entering the state “state_2”, the variable “x” is to be assigned the value 3.

Furthermore, at lines 23-25, the edge declaration “edge edge_1 dest state_2 (x==1) {y=1;};” defines a Mealy expression, “y=1”. The Mealy expression “y=1” signifies that upon the finite state machine transitioning according to an edge defined with reference to the edge declaration “edge_1”, the variable “y” is to be assigned the value 1.

Through the use of conditional expressions associated with edges, Moore expressions, and Mealy expressions, the data describing an augmented finite state machine is capable of expressing a complex digital circuit behaviour. In particular, since conditional expressions may have their result altered by variables which are input circuit signals, and since Moore and Mealy expressions may set the values of output signals, the data describing an augmented finite state machine is capable of expressing a complex input-output behaviour for a digital circuit.

The data describing an augmented finite state machine may specify or imply the following order of evaluation for expressions—conditional expressions associated with edges, Moore expressions and Mealy expressions. For any particular state, the Moore expressions defined for the particular state are evaluated. Then, the edge-transition conditional expressions of the particular state are evaluated. Then, having determined the particular edge according to which the finite state machine is to transition to the next state, the Mealy expressions defined for the particular edge are evaluated. Then, the expressions at the next state are evaluated in the same order as described above, that is, first Moore expressions defined for the next edge, then edge-transition conditional expressions, then the Mealy expressions of the edge along which the transition occurs.

Advantageously, the data describing an augmented finite state machine may specify or imply the following order of evaluation between Moore expressions defined for a state. First, all Moore expressions assigning their result to a registered circuit signal may be evaluated simultaneously. Then, any Moore expressions assigning their result to a combinational signal may be evaluated in sequence, in the order in which they were specified in the corresponding state declaration. Mealy expressions defined for an edge may be evaluated in the order they are defined. Such an order of evaluation enables the timing target of one state transition per clock cycle to be met in the schedule constructed at step 4200 and in the generated hardware description.

Nevertheless, the skilled person will recognise that a different order of evaluation between Moore expressions defined for a state and between Mealy expressions defined for an edge may be possible, as long as this order of evaluation is well-defined and enables the timing target of one state transition per clock cycle to be met.

Furthermore, it may be ensured that Mealy expressions in the data describing an augmented finite state machine assign their result to a variable corresponding to a combinational circuit signal, such that no Mealy expression assigns its result to a variable corresponding to a registered circuit signal. Indeed, a registered circuit signal can only be written to on the rising edge of the clock signal. However, Mealy expressions are not provided to be evaluated at the rising edge of a clock signal. Therefore, enabling a registered signal to be set by a Mealy expression would necessitate the use of a latch, which is undesirable due to its sensitivity to hazards. For this reason, it may be the case that no Mealy expressions assign their result to a registered circuit signal.

In addition, it may be ensured that all conditional expression associated with edges take input variables corresponding to registered circuit signals or input circuit signals. This avoids the potentially inconsistent situation where an edge is associated with a conditional expression that takes a particular combinational circuit signal as input, and where the same edge is associated with a Mealy expression that writes to the particular combinational circuit signal. For example, in such a situation, the Mealy expression could change the particular combinational circuit signal such that the conditional expression evaluates to false, meaning that the edge should not be taken. Appropriate constraints can avoid such a paradoxical situation.

The augmented finite state machine described by text file 710 of FIG. 7A may be graphically represented as graph 720 of FIG. 7B, with states 721a-d and edges 722a-d. State 721a is represented as the first state entered by the finite state machine after initialisation, by connecting a reset state 723 to state 721a via an edge 724.

The digital circuit behaviour defined by the text file 710 may thus be taken to be as follows.

The declarations “register int32×2” and “reset state_1” specify that during initialisation, the value 2 is stored in a memory element corresponding to variable “x”, in a 32-bit integer format, and that the current state is given the value “state_1”. Thus, upon completing initialisation, the memory element corresponding to the variable “x” will hold the value 2, and the current state will be “state_1”.

The state declaration “state state_1 (edge_1, edge_2) { }” specifies that state “state_1” does not have any Moore expressions, and has two outgoing edges, defined with reference to the edge declarations “edge_1” and “edge_2”.

Thus, upon completing initialisation, the digital circuit evaluates the conditional expressions associated with the outgoing edges of state “state_1”.

The edge declaration “edge edge_1 dest state_2 (x==1) y=1;}” is associated with the conditional expression “x==1” which, at initialisation, is not true given that the variable x has the value 2.

The edge declaration “edge edge_2 dest state_3 (x==2) y=2;}” is associated with the conditional expression “x==2” which, at initialisation, is true. The digital circuit therefore evaluates the Mealy expression “y=2” and transitions the current state to state “state 3”.

The state declaration “state state_3 (edge_3) y=3; x=5; specifies that state “state_3” is associated with two Moore expressions, “y=3” and “x=5”, and has one outgoing edge, defined with reference to the edge declaration “edge_3”. As the variable “x” corresponds to a registered circuit signal, the expression “x=5” is evaluated prior to entering state “state_3” and the value 5 stored in the memory element corresponding to “x” upon entering state “state_3”, before “y=3” is evaluated.

The edge declaration “edge edge_3 dest state_4 ( ) { }” is not associated with a conditional expression, and does not specify any Mealy expression. Therefore, the digital circuit transitions the current state to state “state_4”.

The state declaration “state state_4 (edge_4) y=4; x=4;}” specifies that state “state_4” is associated with two Moore expressions “y=4” and “x=4”, and has one outgoing edge, defined with reference to edge declaration “edge_4”. As the variable “x” corresponds to a registered circuit signal, the expression “x=4” is evaluated prior to entering state “state_4”, and the value 4 stored in the memory element corresponding to “x” upon entering state “state_4”, before “y=4” is evaluated.

The edge declaration “edge edge_4 dest state_2 ( ) { }” is not associated with a conditional expression, and does not specify any Mealy expression. Therefore, the digital circuit transitions the current state to state “state_2”.

The state declaration “state state_2 ( ) {y=2; x=3;}” specifies that state “state_2” is associated with two Moore expressions “y=2” and “x=3”, and has no outgoing edges. As the variable “x” corresponds to a registered circuit signal, the expression “x=3” is evaluated prior to entering state “state_2”, and the value 3 stored in the memory element corresponding to “x” upon entering state “state_2”, before “y=2” is evaluated.

As state “state_2” has no outgoing edges which can be taken, the next state is inferred by default to be “state_2” again. Therefore, the digital circuit transitions the current state to state “state_2” again, and the Mealy expressions “x=3” and “y=2” are evaluated again. The digital circuit thus remains in state “state_2” until the digital circuit is stopped.

At step 4200, a set of variables each corresponding to a circuit signal, a set of constants, a schedule of one or more elementary instructions, and a state transition table are determined from the data describing an augmented finite state machine.

Each circuit signal corresponding to a variable in the set of variables, and each constant in the set of constants, will be present in the generated hardware description.

The schedule associates each elementary instruction with a state of the finite state machine, such that the instruction is to be performed in a clock cycle where the current state is the state associated with the instruction. Furthermore, the schedule may associate one or more of the elementary instructions each with a variable or expression, to the effect that an instruction is to be performed if the corresponding variable or expression evaluates to true.

The state transition table specifies, for each state, the possible states to which the finite state machine can transition, and, for each possible state, a variable or expression on which the transition depends.

In particular, a set of variables is initialised with the variables defined in the data obtained at step 4100. Each expression defined in the data obtained at step 4100 may then be decomposed into one or more variables, constants and elementary instructions, where each instruction depends on one or more of the variables and constants and assigns a result to one or more variables, and such that the instructions into which an expression is decomposed yield the same result as the expression. A circuit signal may then be defined for each variable thus obtained. The variables and constants obtained from decomposing an expression may then be added to the set of variables and the set of constants, respectively, and each instruction may be inserted in the schedule.

In this way, the set of variables, the set of constants, the schedule of instructions and the state transition table may describe the same input-output behaviour as the augmented finite state machine, while being in a format which can be optimised and from which a hardware description can be generated.

Optimisations may then be performed that transform the set of variables, the set of constants, the schedule of instructions and the transition table, without changing the input-output behaviour, to improve the speed, reduce the size, and reduce the power consumption of the circuit.

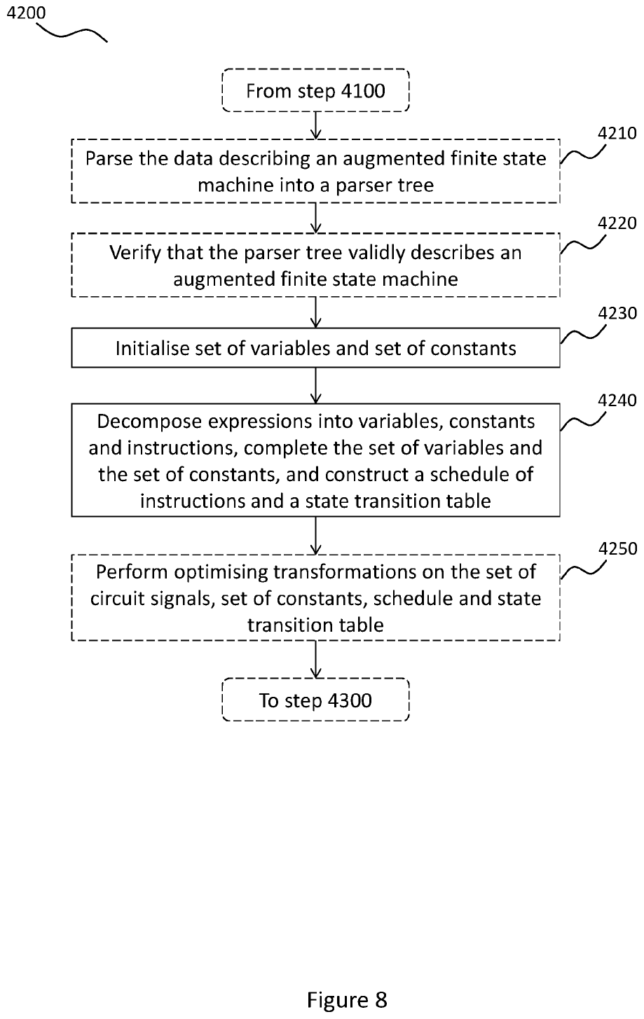

Step 4200 may be performed as steps 4210-4250, described in more detail with reference to FIG. 8.

At step 4210, the data describing an augmented finite state machine may be parsed into an intermediate data structure which is more easily navigated and manipulated by a processor, such as a parser tree.

In particular, if the data describing an augmented finite state machine is a text file as in FIGS. 5A and 7A, the text file may be read, and any state declarations, edge declarations, reset statement, and variable declarations of the text file may be extracted. For each state declaration, any referenced edge declarations and Moore expressions may be extracted; for each edge declaration, its end state, any associated conditional expression, and any associated Mealy expressions may be extracted. For a reset statement, its referenced state declaration may be extracted. For a variable declaration, its identifier, data type, and the signal type of the corresponding circuit signal, namely, whether the corresponding circuit signal is an input, output or internal circuit signal, and whether the corresponding circuit signal is a registered or combinational circuit signal, may be extracted. For each expression, its input variables, a sequence of one or more simpler expressions in terms of which the expression was defined, and the output variable may be extracted.

A parser tree may then be constructed, listing any state declarations, edge declarations, reset statement, and variable declarations in the order in which they appear in the text file: for each state declaration, listing any referenced edge declarations and Moore expressions; for each edge declaration, listing its end state, any associated conditional expression, and any associated Mealy expression; for a reset statement, listing its referenced state declaration; for each variable declaration, listing its identifier, data type, and information concerning the corresponding circuit signal; and for each expression, listing its input variables, the one or more simpler expressions, and the output variable.

Furthermore, the parser tree may be augmented by appending difficult-to-reach information to more accessible places on the parser tree. In particular, for each state declaration, a list of the names of any edges used in the state may be appended to the parser tree with the state declaration. For each Moore expression or Mealy expression, the data type of its input and output variables, and the signal type of the corresponding circuit signals, may be appended to the parser tree with the expression. For each conditional expression, the data type of its input variables and the signal type of the corresponding circuit signals may be appended to the parser tree with the expression.

At step 4220, it may be verified that the parser tree obtained at state 4210 validly describes an augmented finite state machine. If the construction of a parser tree at step 4210 and the verification at step 4220 are successful, the data obtained at step 4100 may be determined to validly describe an augmented finite state machine.

In particular, it may be verified that exactly one state is defined to be the initial state of the finite state machine, and that this state exists; that the identifier of each variable declaration is unique and that each variable has a legal data type and length; that the identifier of each edge declaration is unique and that the end state defined for each edge declaration corresponds to a state declaration; and that the identifier of each state declaration is unique and that any edge referenced in a state declaration corresponds to an edge declaration.

For each Moore expression, it may be verified that each variable used in the expression has a corresponding variable declaration; that the data types of the variables making up the one or more simpler expressions can be used together in those expressions; and that the variable to which the Moore expression assigns its result corresponds to an internal or output circuit signal (not an input circuit signal).

For each Mealy expression, it may be verified that each variable used in the expression has a corresponding variable declaration; that the data types of the variables making up the one or more simpler expressions can be used together in those expressions; and that the Mealy expression assigns its value to a variable corresponding to a combinational circuit signal.

Finally, for each conditional expression associated with an edge, it may be verified that each variable used in the expression has a corresponding variable declaration; that the data types of the variables making up the one or more simpler expressions can be used together in those expressions, and that all the input variables of the conditional expression correspond to registered or input circuit signals.

At step 4230, a set of variables each corresponding to a circuit signal and a set of one or more constants may be initialised. The circuit signals and constants will ultimately be included in the generated hardware description.

In particular, the set of variables may be initialised with the variables already defined in the data defining an augmented finite state machine; those variables may be identified by traversing the parser tree obtained at step 4210.

The set of variables may comprise one or more entries: each entry defines a variable and its corresponding circuit signal. Each entry may specify an identifier of the variable, the data type of the variable, the signal type of the corresponding circuit signal, and optionally, information concerning whether the variable needs to be read, whether the variable needs to be written to, and whether the variable was originally declared in the data describing an augmented finite state machine.

The set of constants may be initialised with the default values of the variables defined in the data defining an augmented finite state machine; these default values may be identified by traversing the parser tree obtained at step 4210.

The set of constants may comprise zero or more entries: each entry may specify an identifier of the constant, a data type for the constant, and the value of the constant.

Then, as expressions are decomposed at the next step, intermediate variables and constants will be obtained. The intermediate variables and corresponding circuit signals will be added to the set of variables, and the constants will be added to the set of constants.

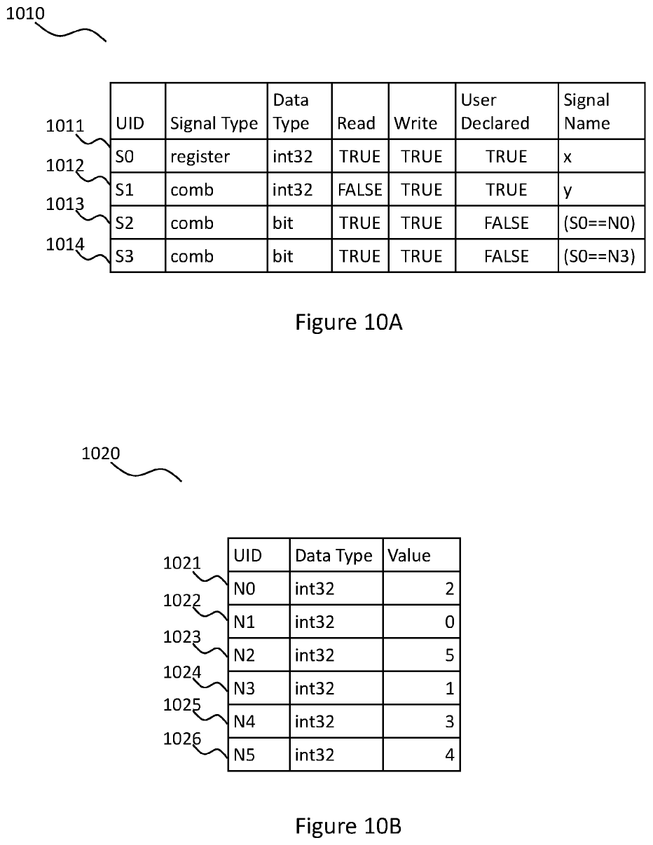

For example, given the text file 710 of FIG. 7 as the data describing an augmented finite state machine at step 4100, at step 4230, an example set of variables 1010 of FIG. 10A may be initialised and an example set of constants 1020 of FIG. 10B may be initialised. Specifically, the set of variables 1010 may be initialised with entries 1011 and 1012 corresponding to the variables that were defined in the data obtained at step 4100. The set of constants 1020 may be initialised empty.

At step 4240, each expression is decomposed into variables, constants and elementary instructions. Based on this, the set of variables and the set of constants are completed, and a schedule of elementary instructions and a state transition table are constructed, such that a digital circuit performing the elementary instructions according to the schedule and updating the value of the current state according to the state transition table has the same input-output behaviour as the augmented finite state machine.

To this end, the states of the finite state machine may be selected one at a time, expressions may be identified using a look-forward algorithm and decomposed into variables, constants and elementary instructions, and the instructions may each be scheduled for the selected state, that is, to be performed in a clock cycle where the current state is the selected state. The schedule may furthermore define for some instructions that they are to be executed if a corresponding variable or expression evaluates to true.

Advantageously, the scheduling of the elementary instructions at step 4240 may guarantee that a timing target of one state transition per clock cycle is achieved, whilst ensuring that the functionality specified by the various expressions—conditional expressions associated with edges, Moore expressions, Mealy expressions—is performed as specified; that is, out-of-order execution hazards are avoided.

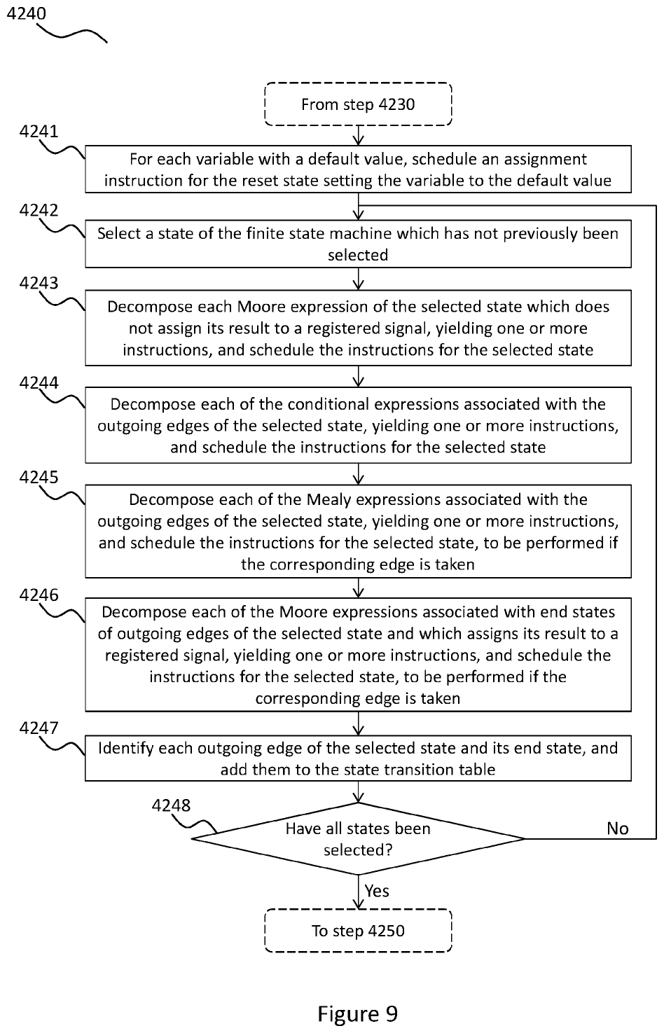

Turning to FIG. 9, step 4240 may be carried out as steps 4241-4248.

Prior to step 4241, an empty schedule and an empty state transition table may be initialised (not shown in FIG. 9).

At step 4241, for each variable with a default value in the data defining an augmented finite state machine, an assignment instruction may be scheduled for the reset state, setting the variable to its default value.

In particular, for each variable with a default value, a constant with this default value may be defined in the set of constants. For each variable with a default value, an entry may then be created in the schedule, assigning the default value to the variable in the reset state.

As explained previously, it may be the case that every variable except variables corresponding to input circuit signals has a default value.

If the reset state is to last more than one clock cycle, for example to ensure that registers are flushed properly before entering the initial state, the instructions assigning to each variable its default value may be scheduled for the first clock cycle of the reset state.

At step 4242, a state of the finite state machine is selected which has never previously been selected.

If a non-zero latency is specified for the selected state, the selected state may be regarded as several separate states, one for each clock cycle spent in the selected state, as described previously at step 4100. Steps 4242-4247 may then be performed separately for each of the several separate states.

At step 4243, each Moore expression of the selected state which does not assign its result to a registered signal is decomposed. This decomposition produces zero or more intermediate variables, zero or more constants and one or more elementary instructions. The elementary instructions are then scheduled for the selected state, the intermediate variables and corresponding circuit signals are appended to the set of variables, and the constants are appended to the set of constants.

To this end, the Moore expressions defined for the selected state may be identified; this may be obtained from the state declaration corresponding to the selected state. The Moore expressions may then be processed in their order of execution specified by the state declaration. For each Moore expression, it may be determined whether the Moore expression assigns a result to a variable corresponding to a registered signal. If the Moore expression assigns a result to a variable not corresponding to a registered signal (i.e. a variable corresponding to an input signal or combinational signal), the method may decompose the Moore expression.

To decompose an expression, method 4000 may repeatedly break the expression into constituent simpler expressions following the syntax of the expression, until the resulting expressions consist of one operator, one or more input variables and/or constants, and one output variable. Each resulting expression then corresponds to an elementary instruction which performs the function of the operator on the one or more input variables and/or constants, and assigns its result to the output variable. By decomposing an expression, intermediate variables used within the expression are also identified: these intermediate variables are the results of elementary instructions which are used in other elementary instructions of the expression.

Based on the decomposition, a circuit signal may also be determined for each of the intermediate variables. For a given intermediate variable, its data type and the signal type of its corresponding circuit signal may be determined from the elementary instruction which assigns its result to the intermediate variable. The intermediate variables and their corresponding circuit signals are then appended to the set of variables.

The constants on which elementary instructions depend may also be identified and appended to the set of constants.

An entry in the schedule may then be created for each elementary instruction obtained from decomposing the Moore expressions of the selected state which do not assign their result to registered signals. The entries may be created in the order in which the elementary instructions are to be executed in a clock cycle when the current state is the selected state. In particular, for any two elementary instructions obtained from the decompositions at step 4243, the order may be chosen as follows. If the elementary instructions both result from decomposing the same expression, then an elementary instruction which depends on the result of the other elementary instruction will be scheduled after the other elementary instruction. If the elementary instructions result from decomposing different expressions, then they may be scheduled in the same order as the order in which the expressions from which they are derived appeared in the data describing an augmented finite state machine.

An entry in the schedule for an elementary instruction may list the state for which the elementary instruction is scheduled (here, the selected state), the variables and/or constants which the elementary instruction takes as input, the variable to which the elementary instruction assigns its result, and the type of the elementary instruction. Additionally, the entry may specify a variable or expression on which the execution of the elementary instruction depends. If such a variable or expression is specified, then the elementary instruction will only be executed if the variable or expression is true. Otherwise, the elementary instruction will be executed regardless of the values of any variables, as long as the current state is the selected state.

The entries created for elementary instructions obtained from decomposing Moore expressions which do not assign their results to registered signals, do not specify variables or expressions on which the execution of the elementary instructions depends, signifying that the elementary instructions are to be executed in a clock cycle where the current state is the selected state, regardless of the values of any variables.

An elementary instruction may take one of several predefined types. An example list of predefined types which elementary instructions can take is shown in Table 1 below:

TABLE 1

| | | Data | Data | |
|---|---|---|---|---|
| | No. | type of | type of | |
| | of | first | second | |
| Name | inputs | input | input | Description |
| ADD | 2 | Any | Any | Add the two input operands together. |
| LOAD | 1 | Any | N/A | Finds where the data of a registered |
| | | | | signal is held in RAM and change the |
| | | | | address of a read port to its location. |
| RASN | 1 | Any | N/A | Write value of input operand to the |
| | | | | registered output. Registered |
| | | | | assignments have a cycle delay and |
| | | | | the data is only ready on the next |
| | | | | cycle |
| CASN | 1 | Any | N/A | Write value of input operand to the |
| | | | | combinational output. Combinational |
| | | | | assignments have no delay and are |
| | | | | ready within the same cycle |
| SUB | 2 | Any | Any | Subtract the two input operands. |
| | | | | Output the result |
| NEG | 1 | Any | N/A | Output the negative value of the input |
| | | | | operand |
| MUL | 2 | Any | Any | Multiply the two input operands. |
| | | | | Output the result |
| DIV | 2 | Any | Any | Divide the two input operand. Output |
| | | | | the result |
| ABS | 1 | Any | N/A | Output the absolute value of the input |
| | | | | operator |
| POW | 2 | Any | Integer | Raise the first operand to the power |
| | | | | of the second. Output the result |
| MOD | 2 | Any | Integer | Perform the modulus of the first |
| | | | | operand by the second operand. |
| | | | | Output the result |
| EXP | 2 | Any | Any | Perform the exponent of the first |
| | | | | operand by the second operand |
| SLL | 2 | Any | Integer | Shift left logic the first operand by |
| | | | | the amount of times determined by |
| | | | | the second operand. |
| SRL | 2 | Any | Integer | Shift Right logic the first operand by |
| | | | | the amount of times determined by |
| | | | | the second operand. |
| SRA | 2 | Any | Integer | Shift Right Arithmetic the first |
| | | | | operand by the amount of times |
| | | | | determined by the second operand. |
| SLA | 2 | Any | Integer | Shift Left Arithmetic the first operand |
| | | | | by the amount of times determined by |
| | | | | the second operand. |
| ROL | 2 | Any | Integer | Rotate Left the first operand by the |
| | | | | amount of times determined by the |
| | | | | second operand. |
| ROR | 2 | Any | Integer | Rotate Right the first operand by the |
| | | | | amount of times determined by the |
| | | | | second operand. |
| BAND | 2 | Boolean | Boolean | Boolean and operation. Compare the |
| | | | | first operand to the second operand |
| | | | | and output Boolean result |
| BOR | 2 | Boolean | Boolean | Boolean or operation. Compare the |
| | | | | first operand to the second operand |
| | | | | and output Boolean result |
| BNAND | 2 | Boolean | Boolean | Boolean nand operation. Compare |
| | | | | the first operand to the second |
| | | | | operand and output Boolean result |
| BNOR | 2 | Boolean | Boolean | Boolean nor operation. Compare the |
| | | | | first operand to the second operand |
| | | | | and output Boolean result |
| BXOR | 2 | Boolean | Boolean | Boolean xor operation. Compare the |
| | | | | first operand to the second operand |
| | | | | and output Boolean result |
| AND | 2 | Any | Any | Bitwise and operation. Compares the |
| | | | | first operand to the second operand |
| | | | | on a bitwise basis and output the |
| | | | | result |
| OR | 2 | Any | Any | Bitwise or operation. Compares the |
| | | | | first operand to the second operand |
| | | | | on a bitwise basis and output the |
| | | | | result |
| NAND | 2 | Any | Any | Bitwise nand operation. Compares |
| | | | | the first operand to the second |
| | | | | operand on a bitwise basis and output |
| | | | | the result |
| NOR | 2 | Any | Any | Bitwise nor operation. Compares |
| | | | | the first operand to the second |
| | | | | operand on a bitwise basis and output |
| | | | | the result |
| XOR | 2 | Any | Any | Bitwise xor operation. Compares the |
| | | | | first operand to the second operand on |
| | | | | a bitwise basis and output the result |
| EQU | 2 | Any | Any | Equal operation. Compares the first |
| | | | | operand to the second. If they are |
| | | | | equal output the Boolean result |
| NEQU | 2 | Any | Any | Not equal operation. Compares the |
| | | | | first operand to the second. If they |
| | | | | are not equal output the Boolean |
| | | | | result |
| GEQU | 2 | Any | Any | Greater than or equal operation. |
| | | | | Compares the first operand to the |
| | | | | second. If the first operand is greater |
| | | | | than or equal to the second operand, |
| | | | | output the Boolean result |
| LEQU | 2 | Any | Any | Less than or equal operation. |
| | | | | Compares the first operand to the |
| | | | | second. If first operand is less than or |
| | | | | equal to the second operand, output |
| | | | | the Boolean result |
| GRE | 2 | Any | Any | Greater than operation. Compares the |
| | | | | first operand to the second. If first |
| | | | | operand is greater than the second |
| | | | | operand, output the Boolean result |
| LES | 2 | Any | Any | Less than operation. Compares the |
| | | | | first operand to the second. If first |
| | | | | operand is less than the second |
| | | | | operand output the Boolean result |

At step 4244, each conditional expression associated with an outgoing edge of the selected state is decomposed into zero or more intermediate variables, zero or more constants and one or more elementary instructions. The elementary instructions are then scheduled for the selected state, the intermediate variables and corresponding circuit signals are appended to the set of variables, and the constants are appended to the set of constants.

In particular, each outgoing edge of the selected state may be identified. For example, the edge declarations referenced in the state declaration corresponding to the selected state may be identified. Then, the zero or more conditional expressions associated with outgoing edges may be identified, and decomposed as explained at step 4243, into zero or more intermediate variables, zero or more constants and one or more elementary instructions.

A circuit signal for each intermediate variable may be determined as explained at step 4243, and the intermediate variables and corresponding circuit signals may then be appended to the set of variables. The constants may be appended to the set of constants.

An entry in the schedule may be then created for each elementary instruction obtained from the decomposition, scheduling each elementary instruction for the selected state. The order of the entries may correspond to the order in which the edges corresponding to the conditional expressions from which the elementary instructions were derived were defined in the state declaration of the selected state, and the order may also take account of the dependencies between elementary instructions as explained at step 4243.

The entries created for elementary instructions obtained from decomposing conditional expressions do not specify variables or expressions on which the execution of the elementary instructions depends, signifying that the elementary instructions are to be executed in a clock cycle where the current state is the selected state, regardless of the values of any variables.

At step 4245, each Mealy expression associated with an outgoing edge of the selected state is decomposed into zero or more intermediate variables, zero or more constants, and one or more elementary instructions. The elementary instructions are then scheduled for the selected state, the intermediate variables and corresponding circuit signals are appended to the set of variables, and the constants are appended to the set of constants.

In particular, each outgoing edge of the selected state may be identified. For each edge, any Mealy expressions associated with the edge may be identified, and decomposed as explained at step 4243, into zero or more intermediate variables, zero or more constants and one or more elementary instructions.

A circuit signal for each intermediate variable may be determined as explained at step 4243, and the intermediate variables and corresponding circuit signals may then be appended to the set of variables. The constants may be appended to the set of constants.

An entry in the schedule may be then created for each elementary instruction obtained from the decomposition, scheduling each elementary instruction for the selected state. The order of the entries may correspond to the order in which the edges associated with the Mealy expressions were defined in the state declaration of the selected state, and the order in which the Mealy expressions were defined in the edge declarations of such edges. The order may also take account of the dependencies between elementary instructions as explained at step 4243.

Additionally, for each schedule entry created for an elementary instruction obtained from decomposing a Mealy expression associated with an outgoing edge of the selected state, a variable on which the execution of the elementary instruction depends may be specified in the entry. This variable may be a variable whose value is true when the edge associated with the Mealy expression is taken, and false otherwise.

At step 4246, each Moore expression associated with the end state of an outgoing edge of the selected state and which assigns its result to a registered signal is identified. Each such Moore expression is then decomposed into zero or more intermediate variables, zero or more constants, and one or more elementary instructions. The elementary instructions are then scheduled for the selected state, the intermediate variables and corresponding circuit signals are appended to the set of variables, and the constants are appended to the set of constants.

In particular, each outgoing edge of the selected state may be identified, and for each outgoing edge, its end state identified. Each Moore expression associated with the end state, and which assigns its result to a registered circuit signal, may then be identified, and decomposed as explained at step 4243, into zero or more intermediate variables, zero or more constants and one or more elementary instructions.

A circuit signal for each intermediate variable may be determined as explained at step 4243, and the intermediate variables and corresponding circuit signals may then be appended to the set of variables. The constants may be appended to the set of constants.

An entry in the schedule may be then created for each elementary instruction obtained from the decomposition, scheduling each elementary instruction for the selected state. The order of the entries may correspond to the order in which the outgoing edges were defined in the state declaration of the selected state, and the order in which the Moore expressions were defined in the state declarations of the end states of the outgoing edges. The order may also take account of the dependencies between elementary instructions as explained at step 4243.

Additionally, for each schedule entry created for an elementary instruction obtained from decomposing a Moore expression associated with an end state of an outgoing edge of the selected state and which assigns its result to a registered signal, a variable on which the execution of the elementary instruction depends may be specified in the entry. This variable may be a variable whose value is true when the outgoing edge associated with the elementary instruction is taken, and false otherwise.

Optionally, after steps 4241 and 4245 have completed, for any variable corresponding to a combinational signal and which has not had its value set by an instruction scheduled for the selected state, an operation may be inserted that sets the variable to its default value. In this way, it may be ensured that the schedule defines the values that are to be taken by the variables corresponding to combinational signals at all times.

At step 4247, each outgoing edge of the selected state is identified, and the end state of each outgoing edge identified. For each outgoing edge, its conditional expression and destination state are then appended to the entry in the state transition table for the selected state. In this way, the state transition table indicates, for each state, the possible states to which the finite state machine can transition, and their associated conditions. As noted above, states with non-zero latency may be regarded as a chain of several distinct states, and this may be reflected in the state transition table, for example by identifying a state by its name and clock cycle number.

Once steps 4243-4247 have been performed for a selected state, all end states of outgoing edges of the selected state which have not previously been selected, may be marked as unvisited.

At step 4248, it may be determined whether all states have been selected. If one state has not been selected, for example, if at least one state is marked as unvisited, then the method may return to step 4242, where a state which has not previously been selected is selected and steps 4243-4247 performed for that state. In particular, the state that has been most recently marked unvisited of the states which have not previously been selected may be selected: this helps cluster together states that have only a few transitions between them in the state transition table.

Otherwise, if all states have been selected, the method may advance to step 4250.

By the end of step 4240, the set of circuit signals, the set of constants, the schedule of elementary instructions and the state transition table obtained at step 4240, may be collectively sufficient to specify the digital circuit behaviour specified by the data describing an augmented finite state machine obtained at step 4100. These four data structures may then serve as the data provided to the next steps of the method 4000. Therefore the augmented parser tree obtained at step 4220 may be discarded at the end of step 4240.

An example operation of step 4240 is now described, assuming that method 4000 received the text file 710 of FIG. 7A as the data describing an augmented finite state machine at step 4100.

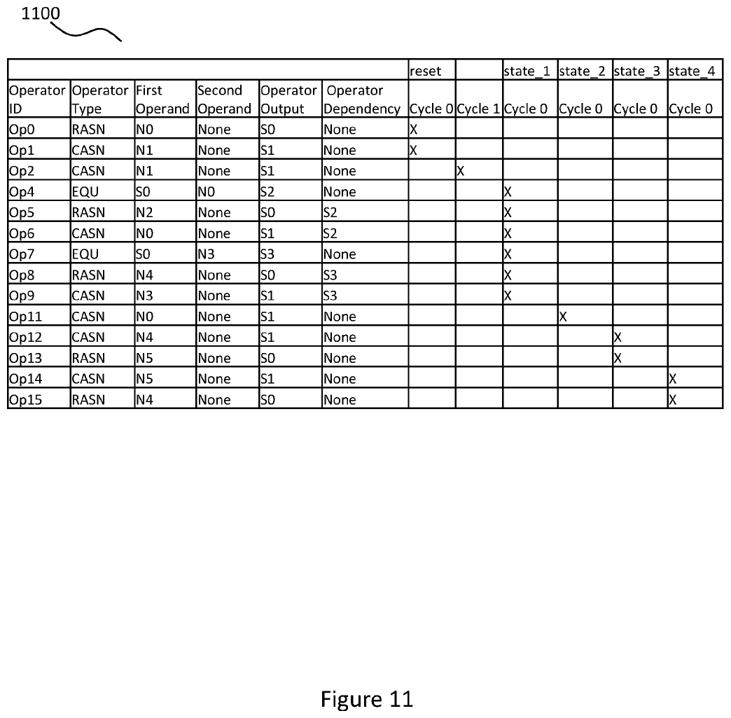

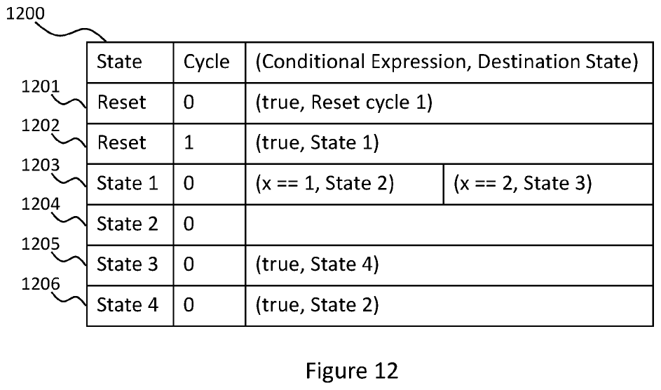

First, an empty schedule and an empty state transition table are initialised. For example, the schedule 1100 of FIG. 11 and the state transition table 1200 of FIG. 12 may be initialised empty.

At step 4241, the variables with default values are identified from the parser tree obtained from the text file 710 of FIG. 7A. “x” has default value 2 and corresponds to a registered circuit signal, and “y” has default value 0 and corresponds to a combinational circuit signal.

Therefore, a constant is defined in the set of constants for each of these default values. Namely, in the set of constants 1020 of FIG. 10B, entries 1021 and 1022, defining respectively a constant “N0” with data type “int32” (the same as the data type of “x”) and value 2, and a constant “N1” with data type “int32” (the same as the data type of “y”) and value 0, are created.

In addition, in the schedule 1100 of FIG. 11, two entries are created in the schedule: one defining an instruction “Op0” of type “RASN” (registered assignment), setting the variable “S0” (which is an identifier for the variable “x”) to the constant “NO” in the reset state; and one defining an instruction “Op1” of type “CASN” (combinational assignment), setting the variable “S1” (which is an identifier for the variable “y”) to the constant “N1” in the reset state. In the particular embodiment described here, the reset state is to last two clock cycles, and so may be regarded as two separate states, one for the first clock cycle to be spent in the reset state, and one for the second clock cycle to be spent in the reset state. The instructions “Op0” and “Op1” are thus scheduled for the first clock cycle of the reset state.

Then, in a first pass through steps 4242 to 4248, the first clock cycle of the reset state 723 is first selected at step 4242. Since the reset state 723 is not associated with any Moore expression assigning its result to a combinational circuit signal, and has exactly one outgoing edge which is not associated with a conditional expression or a Mealy expression, leading to a state with no Moore expressions, steps 4243-4246 have no effect on the schedule. Finally, at step 4247, an entry 1201 is created in the state transition table 1200 of FIG. 12, specifying that the current state is to transition to the second clock cycle of the reset state. The second clock cycle of the reset state is then marked as unvisited. The method then advances to the last state to have been marked unvisited, namely the second clock cycle of the reset state.

In a second pass through steps 4242-4248, the second clock cycle of the reset state is selected at step 4242. As before, steps 4243-4246 have no effect on the schedule. However, since the combinational signal “y” is not assigned a value by any instruction scheduled for the second clock cycle of the reset state, an instruction “Op2” setting the combinational signal “y” to its default value of 0 may be scheduled for the second clock cycle of the reset state. Finally, at step 4247, an entry 1202 is created in the state transition table 1200 of FIG. 12, specifying that the current state is to transition to state “State 1”. State 721a is then marked as unvisited. The method then advances to the last state to have been marked unvisited, namely state 721a.

In a third pass through steps 4242-4248, state 721a is selected at step 4242. Since state 721a is not associated with any Moore expression assigning its result to a combinational signal, step 4243 has no effect on the schedule. State 721a has two outgoing edges 722a and 722b, corresponding to edge declarations “edge_1” and “edge_2” respectively: edge 722a is associated with the conditional expression “x==1” and the Mealy expression “y=1”, and edge 722b is associated with the conditional expression “x==2” and the Mealy expression “y=2”. Therefore, at step 4244, these conditional expressions are decomposed into elementary instructions. “x==1” is decomposed into a constant of value 1, an intermediate variable taking the result of the conditional expression, and an elementary instruction of type “EQU” (equality comparison) taking as input the variable “x”, the constant “1” and outputting its result to the intermediate variable. As a result, a new entry 1014 is created in the set of variables 1010 of FIG. 10A, a new entry 1024 is created in the set of constants 1020 of FIG. 10B, and a new entry for instruction “Op7” is created in the schedule 1100 of FIG. 11. Similarly, the conditional expression “x==2” is decomposed, and a new entry 1013 created in the set of variables 1010 of FIG. 10A and a new entry for instruction “Op4” created in the schedule 1100 of FIG. 11. Because the constant “NO” is already given the value 2 in entry 1021 in the set of constants 1020 of FIG. 10B, it may be reused. Then, at step 4245, the Mealy expression “y=1” may be decomposed, yielding the constant “1” and an elementary instruction of type “CASN” (combinational assignment). As a result, entry 1024 is created in the set of constants 1020 of FIG. 10B, and a new entry for instruction “Op9” is inserted in the schedule, to be performed at state 721a if the result of the conditional expression “x==1”, contained in variable “S3”, is true. Furthermore, the Mealy expression “y=2” may be decomposed, resulting in a new entry for instruction “Op6” to be inserted in the schedule, to be performed at state 721a if the result of the conditional expression “x==2” is true. At step 4246, the outgoing edges leading to states 721b and 721c are followed. The Moore expressions associated with state 721b, “y=2” and “x=3” are identified. Since “x=3” assigns its result to a variable represented by a registered circuit signal, it is decomposed, entry 1025 is created in the set of constants 1020 of FIG. 10B, and a new entry for instruction “Op8” is created in the schedule 1100 of FIG. 11, to be performed at state 721a if the result of the conditional expression “x==1” is true. On the other hand, “y=2” assigns its result to a variable represented by a combinational circuit signal, and so is skipped at this point. Then, the Moore expressions associated with state 721c, “y=3” and “x=5” are identified. Since “y=3” assigns its result to a variable represented by a combinational circuit signal, it is skipped at this point. Since “x=5” assigns its result to a variable represented by a registered circuit signal, it is decomposed, entry 1023 is created in the set of constants 1020 of FIG. 10B, and a new entry for instruction “Op5” is created in the schedule 1100 of FIG. 11, where the instruction “Op5” is to be performed if result of the conditional expression “x==2” is true. Finally, at step 4247, an entry 1203 in the state transition table 1200 of FIG. 12 is created, specifying for state 721a the condition “x==1” and end state “State 2” of the first outgoing edge, and the condition “x==2” and end state “State 3” of the second outgoing edge are appended to the state transition table entry 1203. States 721b and 721c are marked as unvisited. The method then advances to a state to last have been marked unvisited, namely state 721b.

In a fourth pass through steps 4242-4248, at step 4242, state 721b is selected, which is associated with one Moore expression assigning its result to a combinational circuit signal, “y=2”. Therefore, at step 4243, “y=2” is decomposed, and a new entry is created in the schedule 1100 of FIG. 11: this new entry corresponds to operation “Op11” and is scheduled for state 721b. Since state 721b has no outgoing edges, an empty entry 1204 is created for state 721b in the state transition table 1200 of FIG. 12, and the method advances to the unvisited state most recently marked unvisited, state 721c.

In a fifth pass through steps 4242-4248, at step 4242, state 721c is selected. At step 4243, to the Moore expression “y=3” is decomposed, and a new entry is created in the schedule 1100 of FIG. 11, which schedules operation “Op12” for state 721c. State 721c has exactly one outgoing edge with no associated conditional expression or Mealy expression, therefore steps 4244 and 4245 have no effect. Looking forward to the neighbouring state 721d, which is the end state of the outgoing edge of state 721c, state 721d is associated with a Moore expression that assigns its result to a variable corresponding to a registered circuit signal, “x=4”; therefore, this expression is decomposed, a new entry 1026 is created in the set of constants 1020 of FIG. 10B, and a new entry is created in the schedule 1100 of FIG. 11, which schedules operation “Op13” for state 721c at step 4246. Finally, at step 4247, a new entry 1205 is created in the state transition table 1200 of FIG. 12. State 721d is then marked as unvisited; the method then advances to the unvisited state last marked unvisited namely state 721d.

In a sixth pass through steps 4242-4248, at step 4242, state 721d is selected. At step 4243, to the Moore expression “y=4” is decomposed, and a new entry is created in the schedule 1100 of FIG. 11, which schedules operation “Op14” for state 721d. State 721d has exactly one outgoing edge with no associated conditional expression or Mealy expression, therefore steps 4244 and 4245 have no effect. At step 4246, the method looks forward to the neighbouring state 721b, which is associated with a Moore expression, “x=3”, that assigns its result to a variable corresponding to a registered circuit signal. This expression is decomposed, and a new entry is created in the schedule 1100 of FIG. 11, which schedules operation “Op15” for state 721d. Finally, at step 4247, a new entry 1206 is created in the state transition table 1200 of FIG. 12. Since all states have been selected, the method advances to step 4250.

At step 4250, the set of circuit signals, the set of constants, the schedule of elementary instructions and the transition table may be optimised by performing one or more transformations on them which do not alter the input-output behaviour they specify.

For example, a redundant constant optimisation may be performed, whereby any instruction involving only constants as inputs may have its result calculated and replaced by an assignment instruction of type CASN or RASN which assigns the calculated result to the instruction's output variable. This is because an instruction whose inputs are constants will always yield the same result. Performing such a transformation changes the digital circuit behaviour specified by the set of circuit signals, the set of constants, the schedule of elementary instructions and the transition table, as hardware components which would previously have implemented the instruction whose inputs are constants are potentially no longer needed; however, the overall input-output behaviour as seen from outside the digital circuit is left unchanged.

As another example, in states with many elementary instructions in sequence, instructions which may be rescheduled for another state without having an effect on the input-output behaviour of a specified digital circuit may be identified and rescheduled, spreading out the instructions between clock cycles, thereby allowing for a faster clock speed. In particular, an elementary instruction whose result is not needed in the state for which it is scheduled may be re-scheduled for subsequent states; and an elementary instruction whose inputs are not calculated in the state for which it is scheduled may be re-scheduled for previous states.

For example, let there be two states, “state1” and “state2”, where “state1” has a latency of 1 and “state2” comprises the Moore expression “x=1*2*3” where x is a registered signal, and let there be an edge from “state 1” to “state 2”. At step 4246, the two multiplication elementary instructions obtained from the expression will have been scheduled to be performed in the second clock cycle of “state1”, limiting the clock speed to enable both multiplications to complete in one clock cycle. The optimisation may re-schedule the first multiplication for the first clock cycle of “state1”, such that the clock speed is only required to enable one multiplication to complete in a clock cycle.

Returning to FIG. 4, at step 4300, a hardware description is generated based on the set of circuit signals, the set of constants, the schedule of elementary instructions and the state transition table.

Firstly, this hardware description defines a register to store the value of the current state of the finite state machine. In addition, the hardware description defines a circuit signal that inputs to the register storing the current state, which represents the next state of the finite state machine, that is, the value that the current state is to take at the next clock cycle; and a circuit signal that outputs from the register storing the current state which provides the current state of the finite state machine.

The hardware description also comprises the one or more circuit signals corresponding to the variables in the set of variables. For variables that correspond to registered circuit signals, the hardware description also defines a register for each registered circuit signal to store the corresponding variable's value.

The hardware description also comprises one or more expression evaluation logic operations based on the schedule of elementary instructions. The combination of the expression evaluation logic operations takes as input the circuit signal providing the current state of the finite state machine and one or more of the circuit signals corresponding to the variables in the set of variables, and outputs to one or more of the circuit signals corresponding to the variables in the set of variables. At each clock cycle, based on the value of the current state, the expression evaluation logic operations evaluate the elementary instructions scheduled for the current state and set values of one or more circuit signals corresponding to variables in the set of variables.

Finally, the hardware description also comprises one or more state-transition logic operations based on the state transition table. The combination of the state-transition logic operations takes as input the circuit signal providing the current state of the finite state machine and one or more of the circuit signals corresponding to the variables in the set of variables, and outputs to the circuit signal representing the next state of the finite state machine. At each clock cycle, based on the value of the current state and of the variables in the set of variables, the state-transition logic operations set the value of the circuit signal representing the next state in order to perform a state transition in accordance with the state transition table.

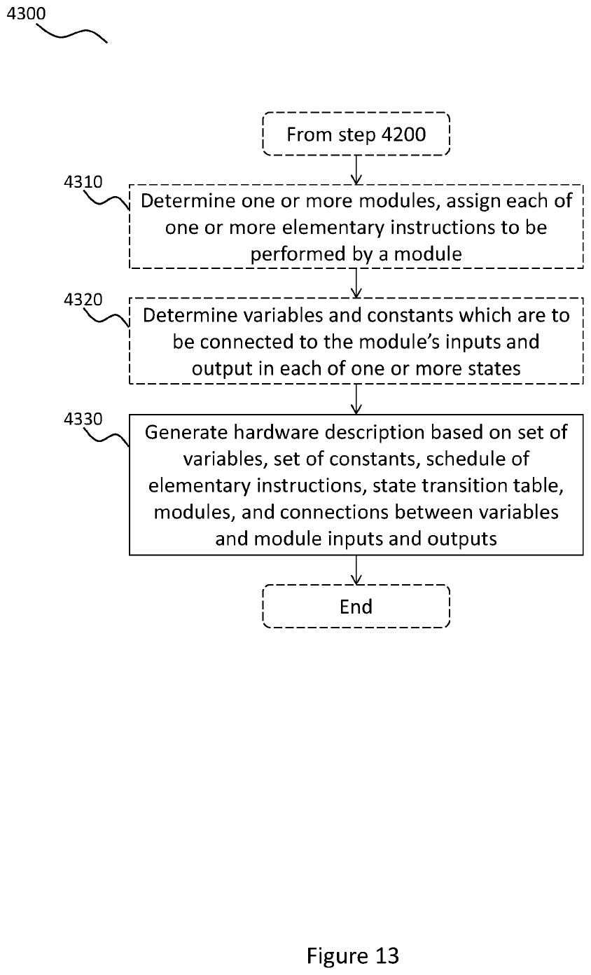

Such a hardware description may for example be generated by method steps 4310-4330 described with reference to FIG. 13, although the skilled person will recognise other ways of generating such a hardware description from the set of variables, set of constants, schedule of elementary instructions, and state transition table.

At step 4310, one or more modules may be defined, and one or more elementary instructions may be assigned to each be performed by a module. In particular, a data structure may be constructed, denoted the module allocator, specifying for each module the elementary instruction which the module is to performs in each state.

A module is a specialised sub-circuit for performing a particular function, such as an adder, multiplier, RAM or ROM. A module may be connected to one or more circuit signals, some of which are inputs of the module and some of which are outputs of the module.

Since similar elementary instructions may be performed in several expressions in the augmented finite state machine, assigning to the same module several elementary instructions which never need to be evaluated in the same clock cycle may lead to a large saving in circuit size. Furthermore, for a particular elementary instruction, several module designs may exist that can perform the elementary instruction, each of which may be optimised for a certain hardware technology—such as a specific FPGA model—and optimised for speed, circuit area, and/or power consumption. Therefore, the output hardware description may be optimised by selecting an appropriate module design for the module implementing the particular elementary instruction.

However, method 4000 does not necessarily assign all elementary instructions to modules. In particular, the “RASN” (registered assignment) and “CASN” (combinational assignment) elementary instructions need not be assigned to modules, because they simply assign one variable to another, so that no calculation needs to be performed.

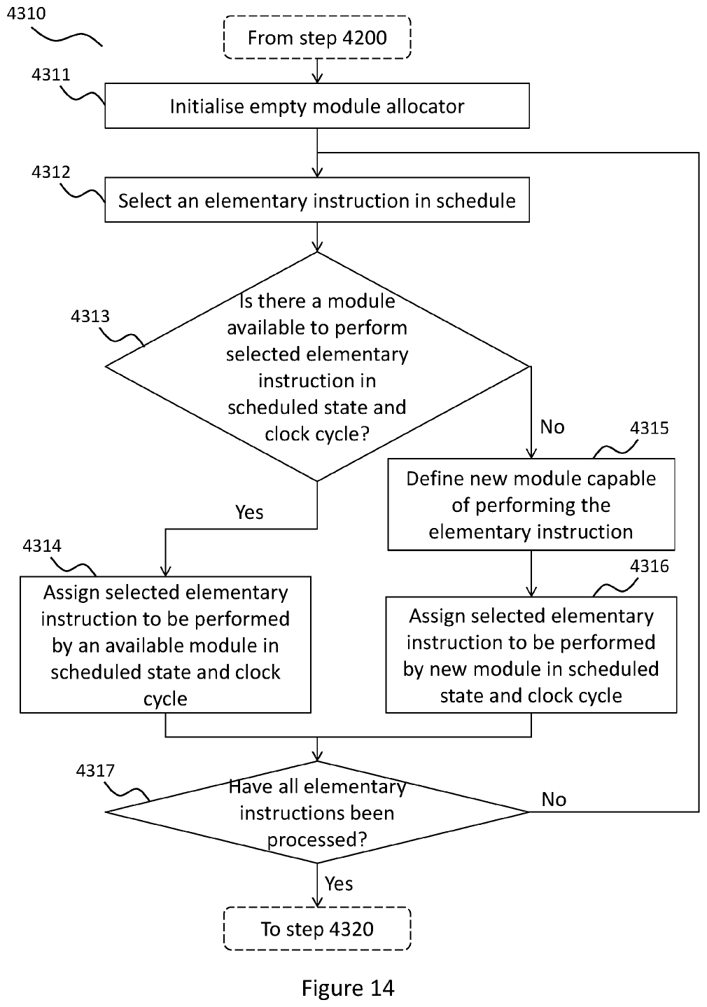

Step 4310 is described in more detail as steps 4311-4317 with reference to FIG. 14.

At step 4311, an empty module allocator data structure is initialised.

At step 4312, an elementary instruction in the schedule for a particular state, which has not previously been selected, is selected. For example, at the first pass through step 4312, the first elementary instruction in the schedule may be selected.

At step 4313, it is determined whether a module in the module allocator is available to perform the selected elementary instruction in the scheduled state. A module in the module allocator is available to perform the selected elementary instruction in the selected state if: the module is capable of performing the elementary instruction, and does not yet have an elementary instruction assigned to be performed by it in the scheduled state. For example, a 32-bit integer adder module may be capable of performing an elementary instruction that adds two 32-bit integers, but may equally be capable of performing an elementary instruction that subtracts two 32-bit integers, or adds two 16-bit integers.

If there is an available module to perform the selected elementary instruction in the scheduled state, the selected elementary instruction is assigned to be performed by an available module in the scheduled state at step 4314. That is, an entry may be created in the module allocator, indicating that the available module is to perform the selected elementary instruction at its scheduled state and clock cycle. Method 4000 then advances to step 4317.

Otherwise, at step 4315, a new module capable of performing the elementary instruction is defined. This new module may be selected from among several module designs such that the new module is optimised for a target hardware technology, and closely matches a desired speed/circuit area/power consumption trade-off indicated via parameters provided to the method 4000. For example, if the elementary instruction is an addition of two 32-bit integers, a 32-bit integer adder of a particular design may be added to the module list. The method then advances to step 4316.

At step 4316, the selected elementary instruction is assigned to be performed by the new module in the scheduled state and clock cycle. In particular, an entry may be created in the module allocator, indicating that the newly defined module is to perform the selected elementary instruction at its scheduled state and clock cycle. The method then advances to step 4317.

At step 4317, it is checked whether all elementary instructions in the schedules for each state and clock cycle have been processed. If there is an elementary instruction which has not yet been selected, the method continues with another pass through steps 4312-4317, where a previously unselected elementary instruction in a schedule is selected, and assigned to be performed by a module. Otherwise, all elementary instructions have been assigned to be performed by a module at their scheduled state and clock cycle, and the method advances to step 4320.

For example, given the example set of variables of FIG. 10A, the example set of constants of FIG. 10B, the example schedule of FIG. 11 and the example state transition table of FIG. 12, step 4310 can be performed as follows.

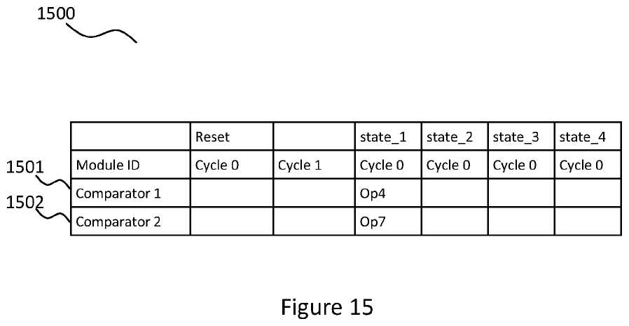

At step 4311, the module allocator 1500 of FIG. 15 is initialised empty.

In a first pass through steps 4312-4317, at step 4312, elementary instruction “Op4” of the schedule of FIG. 11 is selected, as the first elementary instruction in the schedule which is not of type “RASN” or “CASN”. “Op4” is of type “EQU” (equality comparison) and is scheduled to be performed in state “state_1”. At step 4313, the module allocator is empty, so there is no available module to perform the instruction “Op4”, so the method advances to step 4315. At step 4315, a new comparator module “Comparator 1” is defined by creating entry 1501 in the module allocator 1500 of FIG. 15, and operation “Op4” is assigned to be performed by it in state “state_1” at step 4316. At step 4317, there is still another elementary instruction to process, operation “Op7”, so the method returns to step 4312.

In a second pass through steps 4312-4317, at step 4312, elementary instruction “Op7” is selected. “Op7” is also of type “EQU” and is also scheduled to be performed in state “state_1”. At step 4313, since the only comparator defined in the module allocator is already in use in state “state_1”, there is no available module to perform the instruction “Op7” in state “state_1”. Therefore the method advances to step 4315. At step 4315, a new comparator module “Comparator 2” is defined by creating entry 1502 in the module allocator 1500 of FIG. 15, and operation “Op7” is assigned to be performed by it in state “state_1” at step 4316. At step 4317, all elementary instructions which are to be assigned to modules having been processed, the method continues to step 4320.

Returning to FIG. 13, at step 4320, variables and constants which are to be connected to the module's inputs and output in each of one or more states are determined, based on the assignment of elementary instructions to modules obtained at step 4310, and the set of circuit signals, the set of constants, the schedule of elementary instructions and the state transition table obtained at step 4200. A variable or constant is said to be connected to an input of a module in a state if the input is to take the value of the variable in the state, and a variable or constant is said to be connected to an output of a module in a state if the variable is to take the value of the output in the state. A data structure called the module linker is then constructed, specifying for each module and each state the variables and constants which are to be connected to the module in the state.

In particular, for each module in the module allocator data structure and for each state, the elementary instruction assigned to be performed by the module in the state, if there is any, may be identified. For each elementary instruction which is assigned to a module, the one or more input variables of the instruction and the output variable of the instruction may be identified from the schedule.

For each module and for each state, the inputs of the module are to take the values of the input variables of the elementary instruction that is assigned to the module for the state, if there is any, while in the state. The output variable of the elementary instruction is to take the value of the output of the module in the state. In this way, for each module and each state, the variables that are to be connected to the inputs and output of the module in the state, if there are any, are determined.

An entry in the module linker is then created for each elementary instruction, specifying the module inputs and output to which the input and output variables of the elementary instruction are to be connected, and the state in which this assignment is to occur.

Furthermore, the module linker may be analysed for redundant circuit signals. Redundant circuit signals are circuit signals that act as an intermediate circuit signal between two modules where removing the circuit signal and linking the two modules together does not affect functionality.

As an example, given the example set of variables of FIG. 10A, the example set of constants of FIG. 10B, the example schedule of FIG. 11, the example state transition table of FIG. 12, and the example module allocator of FIG. 15, step 4320 may be performed as follows.

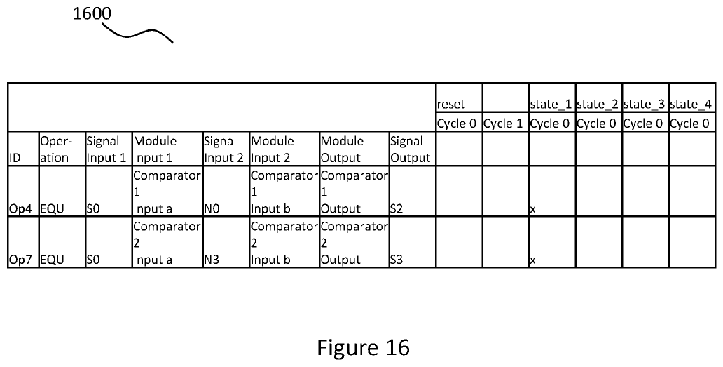

The elementary instructions which are assigned to modules, “Op4” and “Op7”, are identified from the module allocator 1500 of FIG. 15. For each of these elementary instructions, a module linker entry is created, resulting in the module linker 1600 of FIG. 16.

In particular, a first entry in the module linker 1600 is created for elementary instruction “Op4”, specifying that in state “state_1”, the first input of the comparator “Comparator 1” is to take the value of variable “S0”, the second input of “Comparator 1” is to take the value of constant “N0”, and the variable “S2” is to take the value of the output of “Comparator 1”.

In addition, a second entry in the module linker is created for elementary instruction “Op7”, specifying that in state “state_1”, the first input of the comparator “Comparator 2” is to take the value of variable “S0”, the second input of “Comparator 2” is to take the value of constant “N3”, and the variable “S3” is to take the value of the output of “Comparator 2”.

At step 4330, a hardware description implementing the augmented finite state machine is generated, based on the set of variables, set of constants, schedule of elementary instructions and state transition table obtained at step 4200, and optionally the module allocator obtained at step 4310 and the module linker obtained at step 4320.

In particular, a hardware description language file may be written which is composed of several sections, called shells:

an entity shell, which comprises a top-level description of the HDL file, and comprises the circuit signals corresponding to the variables in the set of variables, which are input or output circuit signals. The entity shell declares these signals to be input or output signals of a digital circuit implementing the HDL file;

a signal shell, which comprises the circuit signals corresponding to the variables in the set of variables, which are not input or output signals of a digital circuit implementing the HDL file, a circuit signal representing the current state of the finite state machine and a circuit signal representing the next state of the finite state machine;

a module definition shell, which comprises a definition of the functionality of each module in the module allocator;

a module instance shell, which comprises a declaration of one or more instances of each module in the module definition shell, where each instance corresponds to one module in the module allocator;

a combinational shell, which comprises logic operations effective to connect circuit signals to inputs and outputs of modules depending on the value of the current state, in accordance with the module linker, logic operations depending on the current state and the circuit signals corresponding to the variables in the set of variables, where these logic operations are effective to evaluate the elementary instructions which have not been assigned to modules, in accordance with the schedule, and logic operations depending on the circuit signals corresponding to the variables in the set of variables which are effective to determine the next state of the finite state machine in accordance with the state transition table; and

a synchronous shell, which comprises one or more logic operations signifying that provision is to be made for one or more memory elements to store a value for each variable corresponding to a registered circuit signal, and for one or more memory elements to store the value of the current state of the finite state machine, and comprises one or more logic operations effective, at every clock period, to update the value stored as the current state of the finite state machine with the value of the circuit signal representing the next state, and comprises one or more logic operations effective, at every clock period, to update the values stored in the memory elements storing values for the variables corresponding to registered circuit signals with new values which have been computed in the combination shell.

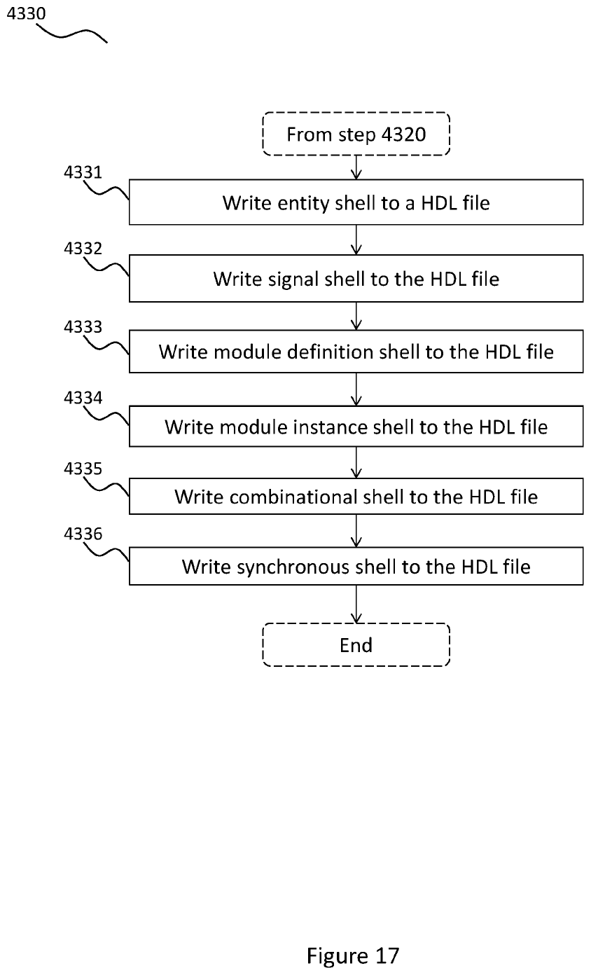

Step 4330 may for example be performed as the steps 4331-4336 of FIG. 17.

At step 4331, an entity shell is written to a HDL file. The HDL file may for example be an empty file, or may alternatively be a non-empty file comprising an incomplete hardware description with which the output of method 4000 will be combined to describe a digital circuit.

The entity shell may optionally comprise statements that declare libraries to be used in the HDL file. In addition, the entity shell comprises a definition of the digital circuit's external interface, that is, the digital circuit's input and output circuit signals. To this end, the set of variables obtained at step 4200 may be traversed, and any input circuit signals or output circuit signals corresponding to variables in the set of variables may be identified. In addition, circuit signals such as an external clock signal or an external reset signal may also be identified as forming part of the digital circuit's external interface.

At step 4332, a signal shell is written to the HDL file. In particular, the set of variables may be traversed, and any circuit signals corresponding to variables which were not identified at step 4331 may be identified. For each identified circuit signal, a statement in a hardware description language declaring the circuit signal may then be written to the file.

At step 4333, a module definition shell is written to the HDL file. In particular, the module allocator may be traversed, and a list of the types of modules used may be constructed. Two modules in the module allocator are said to be instances of the same type if their functionality can be defined using a shared definition in a hardware description language. For each module type in the list, a module definition is then written to the HDL file, describing the external interface of the module, which ensures compatibility with the module regardless of the module's internal architecture. Typically, the module definitions may be provided by third parties such as a FPGA vendor.

At step 4334, a module instance shell is written to the HDL file. In particular, the module allocator may be traversed, and a module instance declaration may be written to the HDL file for each module in the module allocator. Each module instance declaration may refer to a module definition.

At step 4335, a combinational shell is written to the HDL file. The combinational shell comprises a case statement which specifies a set of logic operations for each possible state of the finite state machine, to be performed if the current state is that possible state. For each state, the logic operations are determined as follows.

First, the elementary instructions scheduled for a state may be identified based on the schedule of instructions. For each instruction scheduled for the state, which is not assigned to a module, and which is not of the “RASN” (registered assignment) type, logic operations which perform the instruction may be defined in a hardware description language and inserted in the case statement, to be performed if the current state is the state.

Furthermore, each connection to be established between a circuit signal and an input or output of a module in the state may be identified from the module linker. These connections may be of three types: connections between a circuit signal and an input to a module, connections between a combinational circuit signal and an output of a module, and connections between a registered circuit signal and an output of a module. Logic operations causing the identified connections of the two first types, that is, circuit signals connected to module inputs, and combinational circuit signals connected to module outputs, may be defined in a hardware description language, and inserted in the case statement, to be performed if the current state is the state.

In addition, the outgoing edges of the state and corresponding conditional expressions are identified from the state transition table. For each state, logic operations setting the value of the next state in accordance with the state transition table may be defined in a hardware description language and inserted in the case statement.

At step 4336, a synchronous shell is written to the HDL file. The synchronous shell is a block of hardware description code, which comprises statements in a hardware description language defining registers and describing how the values stored in the registers are to be updated at each clock cycle.

To this end, logic operations may be defined in a hardware description language in the synchronous shell, defining that, at each clock transition, the value of the circuit signal representing the next state of the finite state machine is to be stored in the register holding the current state of the finite state machine. This ensures the timing target of one state transition per clock cycle.

The synchronous shell may further comprise a case statement which specifies logic operations for each state of the finite state machine, to be performed if the current state is the state. For each state, the logic operations may be determined as follows.

The elementary instructions scheduled for the state, of type “RASN” (registered assignment) and which assign a variable or a constant to a variable corresponding to a registered circuit signal, may be identified based on the schedule of instructions. For each such instruction, logic operations may be inserted in the case statement, to be performed if the current state is the state, which are effective to assign the value of the variable or the constant to be stored in the register corresponding to the registered circuit signal.

In addition, each connection between a registered circuit signal and an output of a module in the state may be identified from the module linker. For each such connection, logic operations may be inserted in the case statement, to be performed when the current state is the state, effective to assign the output of the module to be stored in the register corresponding to the registered circuit signal.

The hardware description generated at step 4300 thus specifies a behaviour of a digital circuit, which matches that specified by the data describing an augmented finite state machine obtained at step 4100. The generated hardware description is suited for synthesis into a configuration that can be loaded onto a FPGA or into a circuit layout that can be manufactured.

An example operation of step 4330 is now described, given the example set of variables of FIG. 10A, the example set of constants of FIG. 10B, the example schedule of FIG. 11, the example state transition table of FIG. 12, the example module allocator of FIG. 15 and the example module linker of FIG. 16.

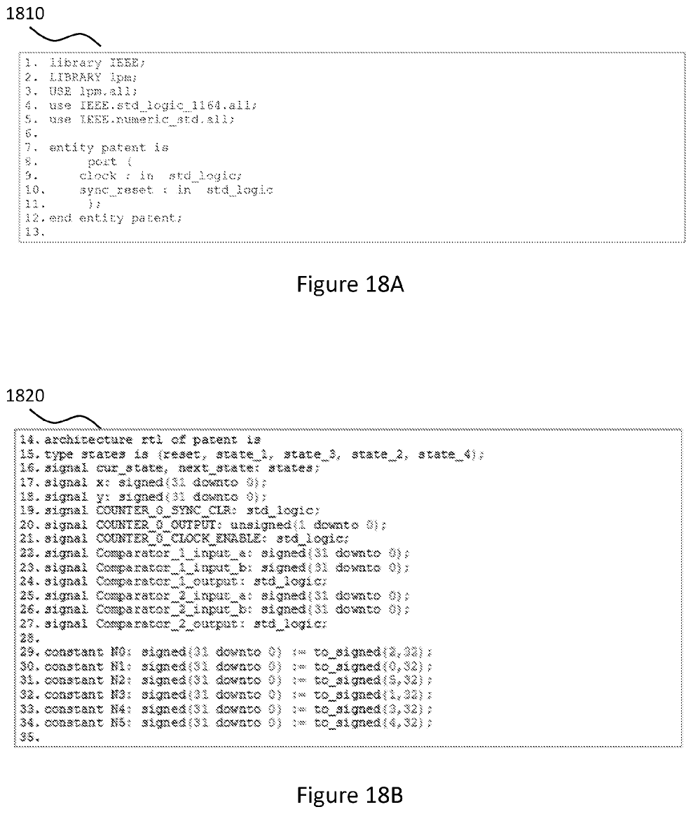

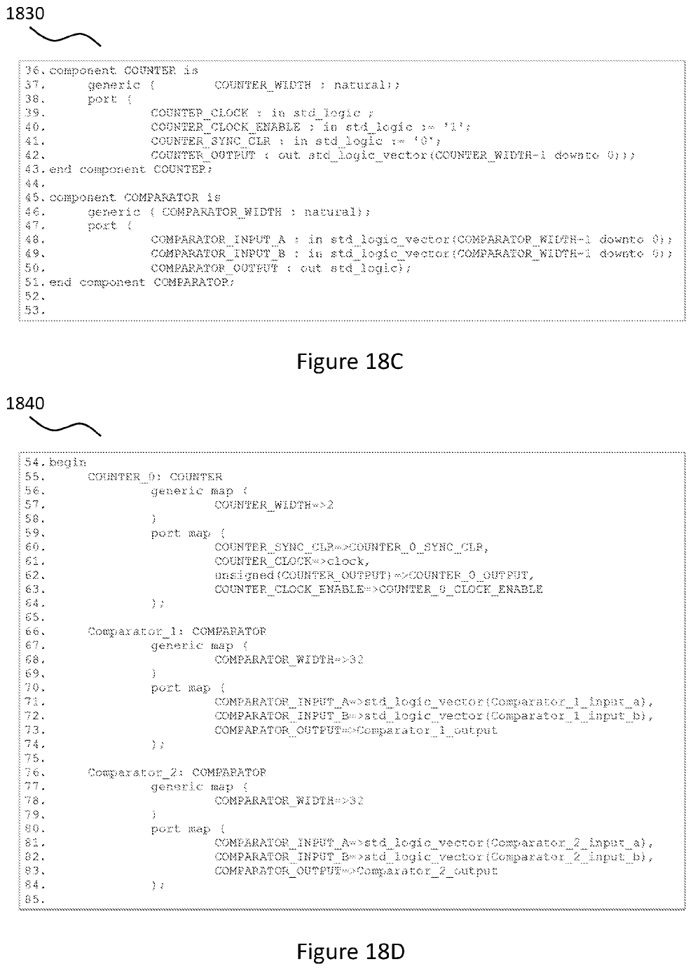

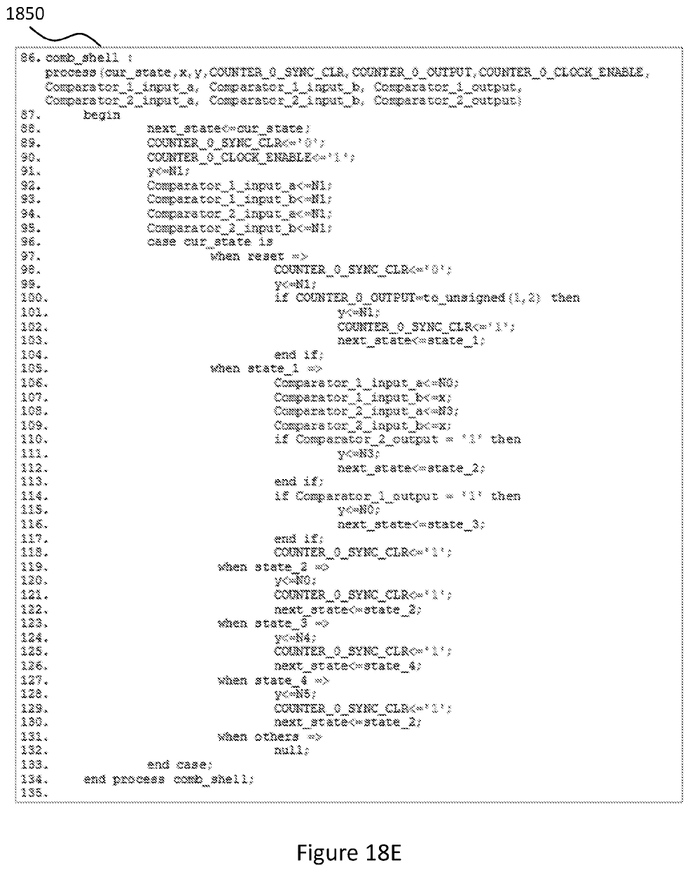

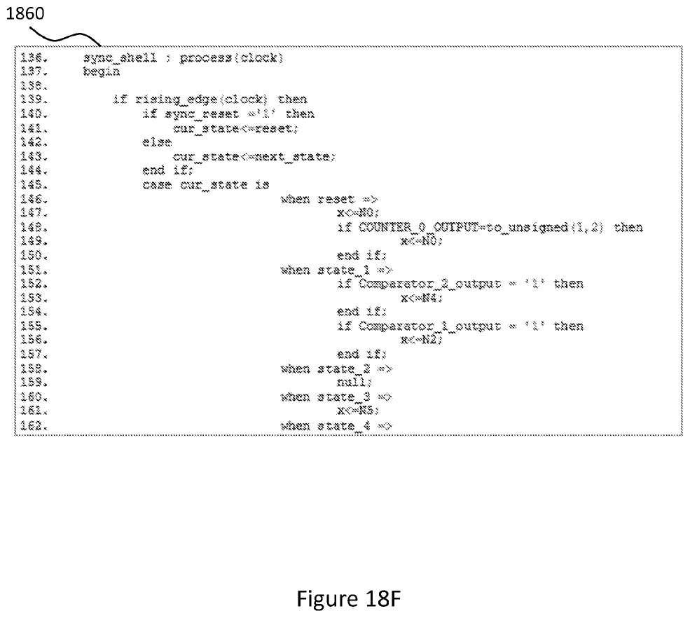

At step 4331, the example set of variables of FIG. 10A is traversed: none of the variables correspond to input or output circuit signals, therefore the example entity shell 1810 of FIG. 18A is written to an empty HDL file. At lines 1-5, this entity shell lists libraries to be used in the HDL file, and at lines 7-12, defines the external interface of the digital circuit to have two input circuit signals, one input clock signal and one input reset signal.

At step 4332, the example set of variables of FIG. 10A is traversed again, and the two circuit signals corresponding to variables (none of which are input or output circuit signals) are included in the signal shell 1820 of FIG. 18B, at lines 17 and 18. The signal shell also defines circuit signals, “cur state” and “next state”, to represent the current state and the next state of the finite state machine, at lines 15 and 16, and circuit signals to represent the inputs and outputs of the modules, at lines 22-27. In addition, the signal shell comprises definitions of the constants N0-N5 of the example set of constants of FIG. 10B. The signal shell 1820 is then written to the HDL file.

At step 4333, the module allocator is traversed, and it is found that two modules are defined, both which are comparators. Therefore, a module definition shell 1830 of FIG. 18C is created comprising a declaration of a comparator's external interface, at lines 45-51. The module definition shell is then written to the HDL file.

At step 4334, the module allocator is traversed, and it is found that two comparators are to be instantiated in the digital circuit, “Comparator 1” and “Comparator 2”. Therefore, a module instance shell 1840 of FIG. 18D is generated, comprising two module instance declarations at lines 66-74 and lines 76-83 respectively. The module instance shell is then written to the HDL file.

At step 4335, a combinational shell 1850 of FIG. 18E is generated comprising a case statement which depends on the current state of the finite state machine. The elementary instructions to be performed for each state are then identified from the schedule 1100 of FIG. 11.

For each instruction scheduled for the state, which is not assigned to a module, and which is not of the “RASN” (registered assignment) type, logic operations are inserted in the case statement to perform the instruction. Thus the statements at lines 99, 101, 111, 115, 120, 124 and 128 of the combinational shell 1850 are respectively generated from the elementary instructions “Op 1”, “Op2”, “Op6”, “Op9”, “Op 11”, “Op12” and “Op14” of the schedule 1100 of FIG. 11.

For each connection in the module linker which is not connecting the output of a module to a registered circuit signal, logic operations are inserted in the case statement to perform the connection in the specified state. Thus the statements at lines 106, 107 and 110 of the combinational shell define the connections required by the first entry in the module linker 1600 of FIG. 16, and the statements at lines 108, 109 and 114 define the connections required by the second entry in the module linker.

In addition, for each state, logic operations are inserted in the case statement to set the value of the next state in accordance with the entries in the state transition table 1200 of FIG. 12. In particular, the statement at line 103 of the combinational shell corresponds to entry 1201 of the state transition table, the statements at lines 112 and 116 correspond to entry 1203, and the statements at lines 122, 126 and 130 respectively correspond to entries 1204, 1205 and 1206. The combinational shell 1850 is then written to the HDL file.

At step 4336, a synchronous shell 1840 of FIG. 18F is generated. The synchronous shell comprises statements to update, at each clock transition, the value of the current state to be the value of the next state, thereby specifying a register to store the value of the current state. In the example synchronous shell, these are the statements at lines 139-144.

In addition, the schedule of elementary instructions is traversed, the instructions of type “RASN” are identified, and for each such instruction a statement is generated in the synchronous shell which performs it, thereby specifying a register to store the value of each registered circuit signal. Thus, in the example synchronous shell, the statements at lines 147, 149, 153, 156, 161 and 163 are generated respectively from the instructions “Op0”, “Op5”, “Op8”, “Op13” and “Op15”.

None of the connections in the module linker 1600 of FIG. 16 connect the output of a module to a registered signal, so no logic operations corresponding to such connections are inserted in the synchronous shell.

Finally, the synchronous shell is written to the HDL file.

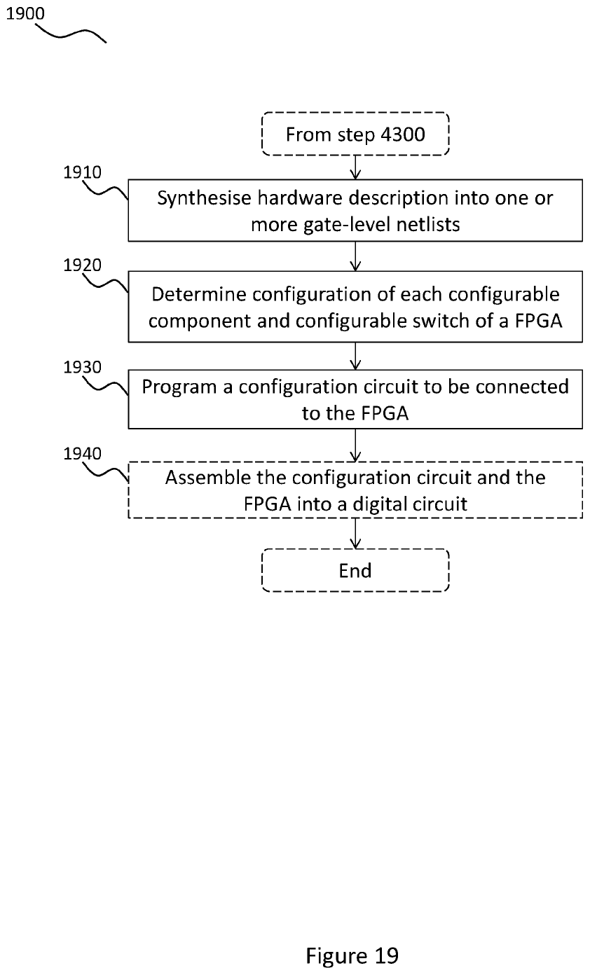

The hardware description generated at step 4300 may then be used to configure a digital circuit comprising a FPGA to implement the generated hardware description. This may be carried out using any of many well-known techniques. In particular, as depicted in FIG. 19, this may involve a step of synthesis into one or more gate-level netlists (1910), a step of placement and routing to determine how each configurable component of the FPGA is to be configured (1920), step of programming a configuration circuit which is to be connected to the target FPGA (1930), and, if necessary, a step of assembling the configuration circuit and the FPGA into a digital circuit (1940). Other methods of obtaining a circuit comprising an FPGA that implements the generated hardware description will also be apparent to the person skilled in the art.

Synthesis and placement and routing are described in more detail in V. Andrei, “FPGA Design Flow-from HDL to physical implementation” [Online, available at https://indico.desy.de/indico/event/7001/session/0/contribution/1/material/slides/0.pdf]

In the synthesis step (1910), the generated hardware description is synthesised into one or more netlists. A netlist is a description of a circuit at a logic gate level, which may for example describe a set of logic gates and their interconnections. The synthesised netlists describe the same input-output behaviour as the generated hardware description. Synthesis may be performed for example by mapping each logic operation of the hardware description to a circuit made of logic gates. Optimisations may be performed to improve the performance of the circuit described by the netlists in terms of reduced circuit size, reduced power consumption and/or increased allowable clock speed. For example, an encoding scheme may be chosen for each circuit signal, such as a one-hot encoding or a binary encoding, in order to optimise circuit performance. For example, circuit signals representing a state of a finite state machine may be identified and encoded using a one-hot encoding, for improved performance.

The netlist may be used in view of configuring a FPGA, as detailed below; alternatively, the netlist may be directly used to produce a digital circuit implementing the generated hardware description, as is well known in the art of ASIC design and manufacture.

In the placement and routing step (1920), the configuration of each configuration component of a target FPGA and the configuration of the configurable switches interconnecting the configurable components is determined. As described previously, a FPGA comprises components such as Configurable Logic Blocks, Digital Signal Processing circuits and Random Access Memory which are configurably interconnected via wires and configurable switches. To this end, in a first step, called mapping, the logic gates described in the netlists may first be each assigned to components of the target FPGA. For example, the one or more netlists may be divided into groups of logic gates, and each group may be assigned to a component such as a Configurable Logic Block, a DSP circuit or a RAM memory. In this way, a list of components needed by a FPGA to implement the generated hardware description may be determined. In a second step, called placement, each of these components is then matched to a specific physical component on the target FPGA. Once this is done, in a third step, called routing, the configurations of the configurable switches needed to interconnect the components are determined. Finally, in a fourth step, the configurations of each configurable component of the target FPGA and of each configurable switch are converted into a bitstream that can be used to program the FPGA.

An overview of the placement and routing process is provided in more detail in Shih-Chun Chen and Yao-Wen Chang, “FPGA placement and routing” [Proceedings of the 36th International Conference on Computer-Aided Design (ICCAD 17)].

The bitstream may then be programmed (i.e. loaded) onto a configuration circuit which is to be connected to the target FPGA (1930). In this way, when the configuration circuit is connected to the FPGA and power is provided to both the configuration circuit and the FPGA, the configuration circuit configures each configurable component and each configurable switch of the FPGA according to the bitstream, and the FPGA then commences operation in such a way that its input-output behaviour is conform to the augmented finite state machine. In some instances, the configuration circuit may be physically located on the FPGA chip; in other instances, the configuration circuit may be located externally from the FPGA, such as on a separate chip connected to the FPGA via a circuit board.

Finally, the configuration circuit and the FPGA may be assembled into a digital circuit if they are not already (1940). For example, the configuration circuit may be electrically connected to the FPGA if it is not already, such that the assembly of the configuration circuit and the FPGA is capable, upon power being provided, of configuring the FPGA to have the same input-output circuit behaviour as originally specified in the data specifying an augmented finite state machine.

1. A computer-implemented method for determining a hardware description which specifies the behaviour of a digital circuit, the hardware description defining a plurality of circuit signals and a plurality of logic operations, wherein each logic operation takes as input one or more circuit signals and outputs to one or more circuit signals, the method comprising:
obtaining data defining a finite state machine, wherein the data defines a plurality of states of the finite state machine, a plurality of edges of the finite state machine, one or more variables on which the finite state machine operates, one or more conditional expressions depending on one or more of the variables, and one or more aspects of the timing and physical implementation of the finite state machine,
wherein each edge specifies a possible transition of the current state of the finite state machine from a respective start state to a respective end state, and
wherein one or more edges of the finite state machine specify a possible transition of the current state from a respective start state to the respective end state in dependence on the value of a respective one of the conditional expressions;
determining one or more expression evaluation logic operations, wherein each conditional expression can be evaluated by one or more of the expression evaluation logic operations;
defining a circuit signal to represent the current state of the finite state machine;
determining one or more state-transition logic operations effective to transition the current state of the finite state machine in accordance with the transitions specified by the edges; and
generating a hardware description which specifies the behaviour of a digital circuit which, in operation, performs the finite state machine, wherein the hardware description comprises the circuit signal representing the current state of the finite state machine, the expression evaluation logic operations, and the state-transition logic operations.

2. The method according to claim 1, wherein the data defining the finite state machine defines one or more circuit signals to each represent a variable, and wherein the hardware description comprises the one or more circuit signals each defined to represent a variable.

3. The method according to claim 2,
wherein a combination of the expression evaluation logic operations takes as input one or more of the circuit signals representing variables and outputs to one or more of the circuit signals representing variables, and
wherein a combination of the state-transition logic operations takes as input the circuit signal representing the current state and the outputs of the expression evaluation logic operations, and outputs to the circuit signal representing the current state of the finite state machine.

4. The method according to claim 2, wherein the data defining the finite state machine additionally defines, for each circuit signal representing a variable, the circuit signal to be either of an input, an internal signal or an output.

5. The method according to claim 2,
wherein the data defining the finite state machine additionally defines, for each of one or more circuit signals representing variables, the circuit signal to be either of a registered signal or a combinational signal, and
wherein determining one or more expression evaluation logic operations further comprises defining, as expression evaluation logic operations, a plurality of logic operations corresponding to one or more registers for storing the registered signals.

6. The method according to claim 1,
wherein the data describing the finite state machine comprises one or more state declarations and one or more edge declarations which together define the plurality of states and the plurality of edges,
wherein each state declaration defines a state of the finite state machine and comprises zero or more references to edge declarations, each corresponding to an outgoing edge of the state, and
wherein each edge declaration comprises exactly one reference to a state declaration, corresponding to the end state of all edges defined with reference to the edge declaration.

7. The method according to claim 1, wherein determining one or more expression evaluation logic operations comprises:
determining a schedule of one or more elementary instructions each scheduled for a state, wherein for any particular state, the elementary instructions scheduled for the particular state are collectively effective to evaluate the conditional expressions on which the edges leading out of the particular state depend.

8. The method according to claim 7, wherein determining one or more expression evaluation logic operations further comprises:
defining, as expression evaluation logic operations, one or more logic operations capable of performing the elementary instructions, such that for each state, all elementary instructions scheduled for that state can be simultaneously evaluated by the one or more logic operations.

9. The method according to claim 8, wherein defining, as expression evaluation logic operations, one or more logic operations capable of performing the elementary instructions comprises:
maintaining a list of modules;
iterating through each elementary instruction in the schedule;
determining for each elementary instruction whether a module in the list is available to perform the operation in the state it is scheduled for:
wherein if a module in the list is available to perform the elementary instruction in the state it is scheduled for, assigning the elementary instruction to be performed by the module in the state it is scheduled for,
otherwise, newly defining a module capable of performing the elementary instruction, inserting the newly-defined module in the list, and assigning the elementary instruction to the newly-defined module; and
defining, for each module, one or more logic operations corresponding to the module as expression evaluation logic operations.

10. The method according to claim 9, wherein defining, for each module, one or more logic operations corresponding to the module as expression evaluation logic operations comprises defining, for each module, one or more logic operations corresponding to the module and optimised for a target hardware as expression evaluation logic operations.

11. The method according to claim 9, wherein at least one of the modules comprises an adder, a multiplier, a random-access memory (RAM) or a read-only memory (ROM).

12. The method according to claim 7,
wherein the data defining the finite state machine further defines, for each of one or more states of the finite state machine, one or more expressions to be evaluated at the state, each taking as input the value of one or more variables and assigning its output value to a variable, and
wherein determining a schedule of one or more elementary instructions each scheduled for a state comprises scheduling for each state one or more elementary instructions such that the elementary instructions scheduled for a state and for each incoming state with an edge leading to the state are collectively effective to evaluate the one or more expressions to be evaluated at the state.

13. The method according to claim 12, wherein scheduling for each state one or more elementary instructions such that the elementary instructions scheduled for a state and for each incoming state with an edge leading to the state are collectively effective to evaluate the one or more expressions to be evaluated at the state comprises:
for each state, scheduling for each incoming state with an edge leading to the state one or more elementary instructions effective to evaluate every expression to be performed at the state which assigns its result to a registered signal.

14. The method according to claim 7,
wherein the data defining the finite state machine further defines, for each of one or more edges of the finite state machine, one or more expressions to be evaluated when the current state of the finite state machine transitions from the edge's start state to the edge's end state, each expression taking as input one or more variables and assigning its output value to a variable, and
wherein determining a schedule of one or more elementary instructions each scheduled for a state comprises, for each state, scheduling for the state one or more elementary instructions, such that the elementary instructions scheduled for the state are collectively effective to evaluate all the expressions defined for all the edges outgoing from the state.

15. The method according to claim 14, wherein determining a schedule of one or more elementary instructions each scheduled for a state further comprises:
verifying that each expression defined for an edge assigns its result to a circuit signal that is a combinational signal.

16. The method according to claim 12, wherein determining a schedule of one or more elementary instructions each scheduled for a state further comprises:
verifying that all variables on which conditional expressions depend are represented by registered signals or input signals.

17. The method according to claim 1, wherein the data defining the finite state machine defines one state of the finite state machine as an initial current state of the finite state machine, and
wherein determining one or more state-transition logic operations comprises defining, as state transition logic operations, one or more logic operations effective to set the circuit signal representing the current state of the state machine to the initial current state upon initialising the digital circuit.

18. The method according to claim 17, wherein the data defining the finite state machine further defines an initial value for each variable upon initialising the digital circuit, and
wherein determining one or more state-transition logic operations further comprises defining, as state transition logic operations, one or more logic operations effective to set, upon initialising the digital circuit, the value of each circuit signal to represent the initial value of the corresponding variable.

19. A process for producing a digital circuit, comprising:
generating a hardware description specifying a behaviour of the digital circuit, wherein generating the hardware description is performed according to the method of:
obtaining data defining a finite state machine, wherein the data defines a plurality of states of the finite state machine, a plurality of edges of the finite state machine, one or more variables on which the finite state machine operates, one or more conditional expressions depending on one or more of the variables, and one or more aspects of the timing and physical implementation of the finite state machine,
wherein each edge specifies a possible transition of the current state of the finite state machine from a respective start state to a respective end state, and
wherein one or more edges of the finite state machine specify a possible transition of the current state from a respective start state to the respective end state in dependence on the value of a respective one of the conditional expressions;
determining one or more expression evaluation logic operations, wherein each conditional expression can be evaluated by one or more of the expression evaluation logic operations;
defining a circuit signal to represent the current state of the finite state machine;
determining one or more state-transition logic operations effective to transition the current state of the finite state machine in accordance with the transitions specified by the edges; and
generating a hardware description which specifies the behaviour of a digital circuit which, in operation, performs the finite state machine, wherein the hardware description comprises the circuit signal representing the current state of the finite state machine, the expression evaluation logic operations, and the state-transition logic operations;
generating a digital circuit layout based on the hardware description; and
manufacturing the digital circuit according to the digital circuit layout.

20. The process according to claim 19, wherein the process is performed for programming a configuration circuit for configuring a Field-Programmable Gate Array, the process further comprising:
determining a configuration for each configurable component of the Field-Programmable Gate Array; and
programming the configuration circuit to configure the configurable components of the Field-Programmable Gate Array according to the determined configuration.

21. A process for configuring a digital circuit comprising a Field-Programmable Gate Array, the process comprising:
programming a configuration circuit for configuring the Field-Programmable Gate Array, wherein programming the configuration circuit comprises:
generating a hardware description specifying a behaviour of the digital circuit;
determining a configuration for one or more configurable components of the Field-Programmable Gate Array;
programming the configuration circuit to configure the one or more configurable components of the Field-Programmable Gate Array according to the determined configuration; and
assembling the configuration circuit and the Field-Programmable Gate Array into the digital circuit, wherein the digital circuit electronically connects the configuration circuit and the Field-Programmable Gate Array.

22. (canceled)

23. (canceled)
